(19) United States
(12) Patent Application Publication
(10) Pub. No.: US 2012/0292626 A1
(43) Pub. Date: Nov. 22, 2012

(54) OPTICAL AND THERMAL ENERGY CROSS-LINKABLE INSULATING LAYER MATERIAL FOR ORGANIC THIN FILM TRANSISTOR

(75) Inventor: Isao Yahagi, Tsuchiura-shi (JP)

(73) Assignee: SUMITOMO CHEMICAL COMPANY, LIMITED, Chuo-ku, Tokyo (JP)

(21) Appl. No.: 13/509,954

(22) PCT Filed: Nov. 10, 2010
(86) PCT No.: PCT/JP2010/069968

§ 371 Date: Aug. 2, 2012

(30) Foreign Application Priority Data
Nov. 17, 2009 (JP) 2009-261966
May 13, 2010 (JP) 2010-110998
Sep. 17, 2010 (JP) 2010-209543

(51) Int. Cl. C08L 39/00; H01L 33/08; B05D 3/06; C08F 236/20; C08F 236/22; C08L 47/00; H01L 29/786; C08F 226/02

(52) U.S. Cl. 257/59; 257/57; 525/151; 526/251; 427/551; 427/558; 257/E33.012; 257/E29.289

(57) ABSTRACT

The problem of the present invention is to provide an organic thin film transistor insulating layer material capable of producing an organic thin film transistor having a small absolute value of threshold voltage and small hysteresis. The means for solving the problem is an organic thin film transistor insulating layer material comprising a macromolecular compound (A) containing repeating units having a fluorine atom-containing group, repeating units having a photodimerizable group and repeating units having a first functional group that generates a second functional group which reacts with active hydrogen by the action of electromagnetic waves or heat, and an active hydrogen compound (B).

### TECHNICAL FIELD

The present invention relates to an organic thin film transistor insulating layer material, which is suitable for forming an insulating layer of an organic thin film transistor.

### BACKGROUND ART

Since organic thin film transistors can be produced at lower temperature than in the case of inorganic semiconductors, a plastic substrate or a film can be used as a substrate of the organic thin film transistor. By using such a substrate, a device which is more flexible than a transistor made of an inorganic semiconductor and is lightweight and non-fragile can be obtained. Moreover, there are cases where a device can be produced by the deposition of thin layers using a method of applying or printing a solution containing an organic material and a large number of devices can be produced on a substrate large in area at lower cost.

Furthermore, since there are a wide variety of materials which can be used for the investigation of transistors, devices widely varyed their characteristics can be produced by using materials differing in molecular structures for the investigation.

In electric field effect type organic thin film transistors which are one of organic thin film transistors, voltage applied to a gate electrode acts on a semiconductor layer through a gate insulating layer, thereby controlling on and off of a drain current. Therefore, a gate insulating layer is formed between the gate electrode and the semiconductor layer.

Further, organic semiconductor compounds used for electric field effect type organic thin film transistors are vulnerable to environmental factors such as humidity, oxygen and the like, and therefore, transistor characteristics tend to deteriorate with time due to humidity, oxygen and the like.

Therefore, in the bottom-gate type organic thin film transistor device structure in which an organic semiconductor compound is uncovered, it is essential to protect the organic semiconductor compound against contact with the external atmosphere by forming an overcoat layer which covers the entire device structure. On the other hand, in the top-gate type organic thin film transistor device structure, an organic semiconductor compound is coated with a gate insulating layer, thereby being protected.

Thus, in organic thin film transistors, an insulating layer material is used in order to form an overcoat layer, a gate insulating layer and the like which cover an organic semiconductor layer. In the present description, an insulating layer or an insulating film of the organic thin film transistor like the overcoat layer and the gate insulating layer is referred to as an insulating layer of an organic thin film transistor. Further, a material used for forming the insulating layer of an organic thin film transistor is referred to as an organic thin film transistor insulating layer material. In addition, the material referred to herein is a concept including amorphous materials such as a macromolecular compound, a composition containing a macromolecular compound, a resin and a resin composition.

The organic thin film transistor insulating layer material is required to have the insulating properties and the characteristics superior in electrical breakdown strength when having been formed into thin film. Further, particularly in the bottom-gate type electric field effect transistors, a semiconductor layer is formed with being laid onto the gate insulating layer. Therefore, the organic thin film transistor gate insulating layer material is required to have affinity with an organic semiconductor so as to form an interface in close contact with the organic semiconductor, and to make a flat surface at an organic semiconductor layer side of a film formed from the organic thin layer transistor gate insulating layer material.

As an art responding to such a requirement, it is described in Patent Document 1 that an epoxy resin and a silane coupling agent are used in combination as a gate organic thin film transistor insulating layer material. In this art, a hydroxyl group produced at the time of a curing reaction of an epoxy resin is reacted with a silane coupling agent. The reason for this is that the hydroxyl group enhances hygroscopicity of the gate insulating layer material and impairs stability of transistor performances.

In Non-Patent Document 1 is described the use of a resin prepared by thermally cross-linking polyvinylphenol and a melamine compound for a gate insulating layer. In this art, by cross-linking with the melamine compound, the hydroxyl groups contained in the polyvinylphenol are removed and the film strength is increased simultaneously. A pentacene TFT having this gate insulating layer has small hysteresis and exhibits durability to a gate bias stress.

In Non-Patent Document 2 is described to use polyvinylphenol and a copolymer prepared by copolymerizing vinylphenol with methylmethacrylate for a gate insulating layer. In this art, the polarity of the whole film is reduced by interaction between the hydroxyl group of vinylphenol and the carbonyl group of methyl methacrylate. A pentacene TFT having this gate insulating layer has small hysteresis and exhibits stable electric properties.

### BACKGROUND ART DOCUMENTS

### Patent Document

Patent Document 1: Japanese Patent Laid-Open Publication No. 2007-305950

### Non-Patent Documents

Non-Patent Document 1: Appl. Phys. Lett. 89, 093507 (2006)
Non-Patent Document 2: Appl. Phys. Lett. 92, 183306 (2008)

### DISCLOSURE OF THE INVENTION

### Problems to be Solved by the Invention

However, when it is considered the practical use of a light-emitting device such as an organic electroluminescence device (organic EL device), it is necessary to improve the operation accuracy of an organic thin film transistor, whereas the above-mentioned conventional organic thin film transistor having a gate insulating layer has a larger absolute value of threshold voltage (Vth) and larger hysteresis.

It is an object of the present invention to provide such an organic thin film transistor insulating layer material that an organic thin film transistor having a small absolute value of threshold voltage and small hysteresis can be produced.

### Means for Solving the Problems

In view of the above-mentioned state of the art, the present inventors made various investigations, and found that the hysteresis of an organic thin film transistor can be reduced by forming a gate insulating layer by the use of a specific resin composition which contains a fluorine atom and which is capable of forming a cross-linked structure. These findings have led to completion of the present invention.

That is, the present invention provides an organic thin film transistor insulating layer material comprising:

a macromolecular compound (A) which contains repeating units represented by the formula:

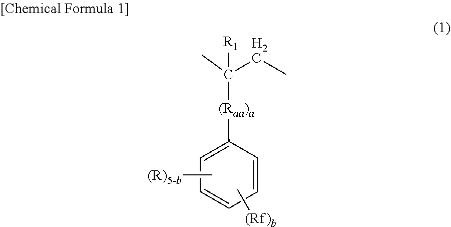

wherein R₁ represents a hydrogen atom or a methyl group; R represents a hydrogen atom or a monovalent organic group having 1 to 20 carbon atoms; Rf represents a fluorine atom or a monovalent organic group having a fluorine atom and having 1 to 20 carbon atoms; Rₐₐ represents a linking moiety that links a main chain with a side chain; a hydrogen atom in the linking moiety may have been substituted with a fluorine atom; a represents an integer of 0 or 1 and b represents an integer of 1 to 5; when there are two or more R's, they may be the same or different; and when there are two or more Rf's, they may be the same or different; and repeating units each containing a functional group which absorbs optical energy or electron beam energy to cause a dimerization reaction, and contains two or more first functional groups in its molecule, wherein the first functional groups are each a functional group that generates, by the action of electromagnetic waves or heat, a second functional group which reacts with active hydrogen, and

at least one active hydrogen compound (B) selected from the group consisting of low-molecular compounds containing two or more active hydrogen atoms in each molecule and macromolecular compounds containing two or more active hydrogen atoms in each molecule.

In one embodiment, the repeating units each containing a functional group which absorbs optical energy or electron beam energy to cause a dimerization reaction are repeating units represented by the formula:

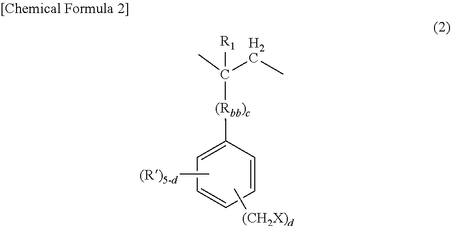

wherein R₂ represents a hydrogen atom or a methyl group; R′ represents a hydrogen atom or a monovalent organic group having 1 to 20 carbon atoms; R_{bb} represents a linking moiety that links a main chain with a side chain; a hydrogen atom in the linking moiety may have been substituted with a fluorine atom; c represents an integer of 0 or 1 and d represents an integer of 1 to 5; when there are two or more R's, they may be the same or different; and X represents a chlorine atom, a bromine atom or an iodine atom.

In one embodiment, the repeating units each containing a functional group which absorbs optical energy or electron beam energy to cause a dimerization reaction are repeating units represented by the formula:

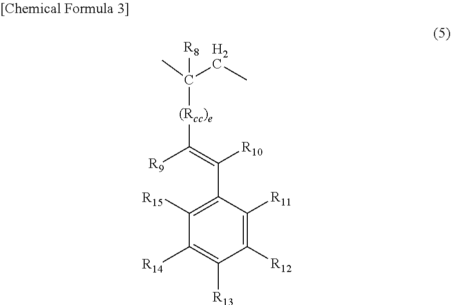

wherein R₈ represents a hydrogen atom or a methyl group; R₉ to R₁₅ are the same or different and represent a hydrogen atom or a monovalent organic group having 1 to 20 carbon atoms; R_{cc} represents a linking moiety that links a main chain with a side chain; a hydrogen atom in the linking moiety may have been substituted with a fluorine atom; and e represents an integer of 0 or 1.

In one embodiment, the repeating units each containing a functional group which absorbs optical energy or electron beam energy to cause a dimerization reaction are repeating units represented by the formula:

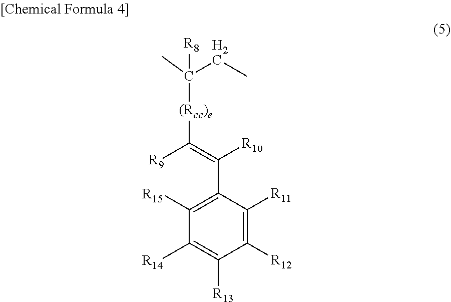

wherein R₁₆ represents a hydrogen atom or a methyl group; R₁₇ to R₂₃ are the same or different and represent a hydrogen atom or a monovalent organic group having 1 to 20 carbon atoms; R_{dd} represents a linking moiety that links a main chain with a side chain; and a hydrogen atom in the linking moiety may have been substituted with a fluorine atom.

In one embodiment, the first functional groups are groups of at least one member selected from the group consisting of an isocyanato group blocked with a blocking agent and an isothiocyanato group blocked with a blocking agent.

In one embodiment, the isocyanato group blocked with a blocking agent and the isothiocyanato group blocked with a blocking agent are groups represented by the formula:

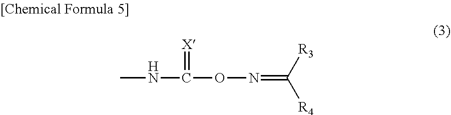

wherein X′ represents an oxygen atom or a sulfur atom, and R₃ and R₄ are the same or different and represent a hydrogen atom or a monovalent organic group having 1 to 20 carbon atoms.

In one embodiment, the isocyanato group blocked with a blocking agent and the isothiocyanato group blocked with a blocking agent are groups represented by the formula:

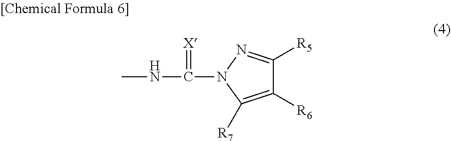

wherein X′ represents an oxygen atom or a sulfur atom, and R₅ to R₇ are the same or different and represent a hydrogen atom or a monovalent organic group having 1 to 20 carbon atoms.

Further, the present invention provides a method for forming an insulating layer of an organic thin film transistor comprising the steps of:

applying a liquid containing the organic thin film transistor insulating layer material according to any one of the above-mentioned embodiments onto a substrate to form an applied layer on the substrate;

irradiating the applied layer with light or electron beams to dimerize a functional group which absorbs optical energy or electron beam energy to cause a dimerization reaction in a macromolecular compound (A); and

applying electromagnetic waves or heat to the applied layer to generate a second functional group from a first functional group of the macromolecular compound (A) and reacting the second functional group with an active hydrogen-containing group of an active hydrogen compound (B).

In one embodiment, the light is ultraviolet light.

Further, the present invention provides an organic thin film transistor having an insulating layer of an organic thin film transistor formed by using the organic thin film transistor insulating layer material according to any one of the above-mentioned embodiments.

In one embodiment, the insulating layer is a gate insulating layer.

Moreover, the present invention provides a member for a display including the organic thin film transistor.

Moreover, the present invention provides a display including the member for a display.

Moreover, the present invention provides a macromolecular compound containing:

repeating units represented by the formula:

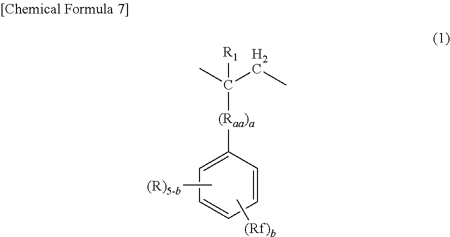

wherein R₁ represents a hydrogen atom or a methyl group; R represents a hydrogen atom or a monovalent organic group having 1 to 20 carbon atoms; Rf represents a fluorine atom or a monovalent organic group having a fluorine atom and having 1 to 20 carbon atoms; Rₐₐ represents a linking moiety that links a main chain with a side chain; a hydrogen atom in the linking moiety may have been substituted with a fluorine atom; a represents an integer of 0 or 1 and b represents an integer of 1 to 5; when there are two or more R's, they may be the same or different; and when there are two or more Rf's, they may be the same or different,

repeating units represented by the formula:

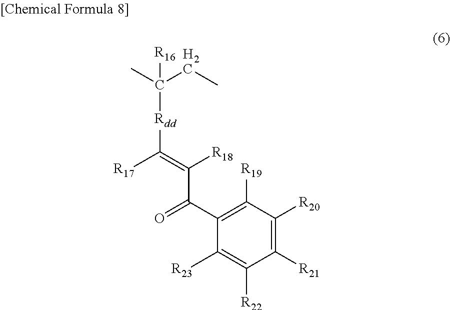

wherein R₁₆ represents a hydrogen atom or a methyl group; R₁₇ to R₂₃ are the same or different and represent a hydrogen atom or a monovalent organic group having 1 to 20 carbon atoms; R_{dd} represents a linking moiety that links a main chain with a side chain; and a hydrogen atom in the linking moiety may have been substituted with a fluorine atom, and

two or more first functional groups in its molecule, wherein the first functional groups are each a functional group that generates, by the action of electromagnetic waves or heat, a second functional group which reacts with active hydrogen.

### Effect of the Invention

An organic thin film transistor having an insulating layer formed by using the organic thin film transistor insulating layer material of the present invention has a small absolute value of threshold voltage and small hysteresis.

### BRIEF DESCRIPTION OF THE DRAWINGS

FIG. 1 is a schematic sectional view showing the structure of a bottom-gate top-contact type organic thin film transistor which is an embodiment of the present invention.

FIG. 2 is a schematic sectional view showing the structure of a bottom-gate bottom-contact type organic thin film transistor which is another embodiment of the present invention.

### MODES FOR CARRYING OUT THE INVENTION

In the present description, a “macromolecular compound” refers to a compound having a structure in which a plurality of the same structural units are present repeatedly in its molecule, and the so-called dimer is included in the macromolecular compound. On the other hand, a “low-molecular compound” refers to a compound which does not have the same structural units repeatedly in its molecule.

The gate organic thin film transistor insulating layer material of the present invention comprises a macromolecular compound (A) and an active hydrogen compound (B). Active hydrogen refers to a hydrogen atom bound to an atom other than a carbon atom such as an oxygen atom, a nitrogen atom or a sulfur atom.

### Macromolecular Compound (A)

The macromolecular compound (A) contains a fluorine atom, a plurality of functional groups which absorb optical energy or electron beam energy to cause a dimerization reaction, and a plurality of first functional groups that generate, by the action of electromagnetic waves or heat, a second functional group which reacts with active hydrogen. Herein, the functional group which absorbs optical energy or electron beam energy to cause a dimerization reaction is referred to as a “photodimerizable group”.

With introduction of fluorine into the organic thin film transistor insulating layer material, the formed insulating layer is low in polarity, and the polarization of the insulating layer is inhibited. In addition, if a cross-linked structure is formed inside the insulating layer, the movement of the molecular structure is inhibited, and thus the polarization of the insulating layer is inhibited. If the polarization of the insulating layer is inhibited, when, for example, the insulating layer is used as a gate insulating layer, the absolute value of threshold voltage of an organic thin film transistor is lowered and operation accuracy is improved.

A fluorine atom is preferably substituted for a hydrogen atom of a side chain or a side group (a pendant group) of a macromolecular compound, rather than for a hydrogen atom of a main chain of the macromolecular compound. If a fluorine atom has been substituted at the side chain or the side group, affinity with other organic materials such as an organic semiconductor does not deteriorate, and this makes it easy to form a layer in contact with an exposed surface of an insulating layer.

In one embodiment, the photodimerizable group is preferably a functional group that generates a carboradical in the case where the functional group absorbs optical energy or electron beam energy. The carboradical can be easily dimerized by radical coupling to form a cross-linked structure within the insulating layer.

In another embodiment, the photodimerizable group is a functional group which can cause a concerted reaction in the case where the functional group absorbs optical energy or electron beam energy. The functional groups which can cause a concerted reaction can be dimerized by mutual addition-cyclization to form a cross-linked structure within the insulating layer.

The light absorbed by the photodimerization-reactive group is preferably high-energy light, since excessively low-energy light may cause a reaction of the photodimerization-reactive group which has been remained at the time when an organic thin film transistor insulating layer material is formed by a photopolymerization method. The light absorbed by the photodimerization-reactive group is preferably ultraviolet light, for example, light having a wavelength of 400 nm or less, and preferably from 150 to 380 nm.

The dimerization as used herein refers to the action that two molecules of organic compound(s) are chemically bonded together. The molecules to be bonded together may be the same or different kind. Also, the chemical structures of functional groups in the two molecules may be the same or different. It, however, is preferred that the functional groups have structure(s) and combination, which allow a photodimerization reaction to occur without using reaction aids such as a catalyst, an initiator and the like. The reason for this is that surrounding organic materials may be deteriorated when they are brought into contact with a residue of the reaction aids.

The first functional group contained in the macromolecular compound (A) does not react with active hydrogen, but if electromagnetic waves or heat acts on the first functional group, the second functional group is generated and this reacts with active hydrogen. That is, the first functional group is deprotected by the electromagnetic waves or heat and generates a second functional group which reacts with active hydrogen. The second functional group reacts with an active hydrogen-containing group of the active hydrogen compound (B) and is bound to this group, and thereby it can form a cross-linked structure within the insulating layer.

The second functional group is protected (blocked) and is present in a resin composition as a first functional group before electromagnetic waves or heat is applied in the step of forming a gate insulating layer. As a result of this, storage stability of the resin composition is improved.

For example, a macromolecular compound containing repeating units having a fluorine atom-containing group, repeating units having a photodimerizable group and repeating units having the first functional group corresponds to the macromolecular compound (A).

A preferred example of the fluorine atom-containing group is an aryl group whose hydrogen atom is substituted with fluorine and an alkylaryl group whose hydrogen atom is substituted with fluorine, particularly a phenyl group whose hydrogen atom is substituted with fluorine and an alkylphenyl group whose hydrogen atom is substituted with fluorine.

A preferred example of the photodimerizable group is an aryl group whose hydrogen atom is substituted with a halomethyl group, a vinyl group whose hydrogen atom at the 2-position is substituted with an aryl group and a vinyl group whose hydrogen atom at the 2-position is substituted with an arylcarbonyl group, and particularly preferred examples include a phenyl group whose hydrogen atom is substituted with a halomethyl group, a vinyl group whose hydrogen atom at the 2-position is substituted with a phenyl group and a vinyl group whose hydrogen atom at the 2-position is substituted with a phenylcarbonyl group. When a fundamental backbone of a side-chain group of the repeating unit is an aryl group or a phenyl group, the affinity for other organic materials such as an organic semiconductor is improved, and in the case of forming a layer containing the organic material, the organic material contacts an exposed surface of the insulating layer and this facilitates formation of a flat layer.

When the aryl group whose hydrogen atom is substituted with a halomethyl group and the phenyl group whose hydrogen atom is substituted with a halomethyl group are irradiated with ultraviolet light or electron beams, a halogen in each group is detached from the group to generate a benzyl type carboradical When two generated carboradicals are bound to each other, a carbon-carbon bond is formed (radical coupling) and the organic thin film transistor insulating layer material is cross-linked. Further, in the case of the vinyl group whose hydrogen atom at the 2-position is substituted with an aryl group or a phenyl group, a vinyl group whose hydrogen atom at the 2-position is substituted with an arylcarbonyl group or a phenylcarbonyl group or the like, if these groups are irradiated with ultraviolet light or electron beams, a [2+2] cyclization reaction occurs and the organic thin film transistor insulating layer material is cross-linked.

The repeating unit having a fluorine atom-containing group is preferably a repeating unit represented by the formula (1). The repeating unit having a photodimerizable group is preferably a repeating unit represented by the formula (2), a repeating unit represented by the formula (5) or a repeating unit represented by the formula (6).

In the formula (1), R₁ represents a hydrogen atom or a methyl group. In one embodiment, R₁ is a hydrogen atom. Rₐₐ is a linking moiety that links a main chain with a side chain. The inking portion may be a divalent group having a structure which does not exhibit reactivity under reaction conditions under which the organic thin film transistor insulating layer material of the present invention is cross-linked. Specific examples of the linking moiety include a bond composed of a divalent organic group having 1 to 20 carbon atoms, an ether bond (—O—), a ketone bond (—CO—), an ester bond (—COO—, —OCO—), an amide bond (—NHCO—, —CONH—), an urethane bond (—NHCOO—, —OCONH—), bonds of combinations of these bonds and the like. A hydrogen atom in the linking moiety may have been substituted with a fluorine atom. a represents an integer of 0 or 1. In one embodiment, a is 0.

Rf represents a fluorine atom or a monovalent organic group having a fluorine atom and having 1 to 20 carbon atoms. In one embodiment, Rf is a fluorine atom.

b represents an integer of 1 to 5. In one embodiment, b is 5.

R represents a hydrogen atom or a monovalent organic group having 1 to 20 carbon atoms.

In the formula (2), R₂ represents a hydrogen atom or a methyl group. In one embodiment, R₂ is a hydrogen atom. R_{bb} is a linking moiety and has the same meaning as Rₐₐ. c represents an integer of 0 or 1. In one embodiment, c is 0.

X represents a chlorine atom, a bromine atom or an iodine atom. In one embodiment, X is a chlorine atom.

d represents an integer of 1 to 5. In one embodiment, d is 5.

R′ represents a hydrogen atom or a monovalent organic group having 1 to 20 carbon atoms.

In the formula (5), R₈ represents a hydrogen atom or a methyl group. In one embodiment, R₈ is a hydrogen atom. R_{cc} is a linking moiety and has the same meaning as Rₐₐ. In one embodiment, R_{cc} is a group represented by the formula —O—C(═O)—. e represents an integer of 0 or 1. In one embodiment, e is 1.

R₉ to R₁₅ represent a hydrogen atom or a monovalent organic group having 1 to 20 carbon atoms. In one embodiment, R₉ to R₁₅ are each a hydrogen atom.

The monovalent organic group having 1 to 20 carbon atoms may be linear, branched or cyclic, and may be saturated or unsaturated.

Examples of the monovalent organic group having 1 to 20 carbon atoms include linear hydrocarbon groups having 1 to 20 carbon atoms, branched hydrocarbon groups having 3 to 20 carbon atoms, cyclic hydrocarbon groups having 3 to 20 carbon atoms and aromatic hydrocarbon groups having 6 to 20 carbon atoms, and preferred examples thereof include linear hydrocarbon groups having 1 to 6 carbon atoms, branched hydrocarbon groups having 3 to 6 carbon atoms, cyclic hydrocarbon groups having 3 to 6 carbon atoms and aromatic hydrocarbon groups having 6 to 20 carbon atoms.

In the linear hydrocarbon groups having 1 to 20 carbon atoms, branched hydrocarbon groups having 3 to 20 carbon atoms and cyclic hydrocarbon groups having 3 to 20 carbon atoms, a hydrogen atom contained in these groups may have been substituted with a fluorine atom.

In the aromatic hydrocarbon groups having 6 to 20 carbon atoms, a hydrogen atom contained in the groups may have been substituted with an alkyl group, a chlorine atom, a bromine atom, an iodine atom or the like.

Specific examples of the monovalent organic group having 1 to 20 carbon atoms include a methyl group, an ethyl group, a propyl group, a butyl group, a pentyl group, a hexyl group, an isopropyl group, an isobutyl group, a tertiary butyl group, a cyclopropyl group, a cyclobutyl group, a cyclopentyl group, a cyclohexyl group, a cyclopentynyl group, a cyclohexynyl group, a trifluoromethyl group, a trifluoroethyl group, a phenyl group, a naphthyl group, an anthryl group, a tolyl group, a xylyl group, a dimethylphenyl group, a trimethylphenyl group, an ethylphenyl group, a diethylphenyl group, a triethylphenyl group, a propylphenyl group, a butylphenyl group, a methylnaphthyl group, a dimethylnaphthyl group, a trimethylnaphthyl group, a vinylnaphthyl group, an ethenylnaphthyl group, a methylanthryl group, an ethylanthryl group, a chlorophenyl group and a bromophenyl group.

An alkyl group is preferred as the monovalent organic group having 1 to 20 carbon atoms.

When Rf is an organic group having a fluorine atom and having 1 to 20 carbon atoms, examples of the monovalent organic group having a fluorine atom and having 1 to 20 carbon atoms include a trifluoromethyl group, a 2,2,2-trifluoroethyl group, a 2,2,3,3,3-pentafluoropropyl group, a 2-(perfluorobutyl)ethyl group, a pentafluorophenyl group, a trifluoromethylphenyl group and the like.

When R, R′ and R₉ to R₁₅ are each a monovalent organic group having 1 to 20 carbon atoms, the monovalent organic group does not have a fluorine atom.

The divalent organic group having 1 to 20 carbon atoms may be linear, branched or cyclic, and may be an aliphatic hydrocarbon group or an aromatic hydrocarbon group. Examples thereof include linear divalent aliphatic hydrocarbon groups having 1 to 20 carbon atoms, branched divalent aliphatic hydrocarbon groups having 3 to 20 carbon atoms, cyclic divalent hydrocarbon groups having 3 to 20 carbon atoms and divalent aromatic hydrocarbon groups having 6 to 20 carbon atoms which may have been substituted with an alkyl group or the like. Among these groups, linear divalent aliphatic hydrocarbon groups having 1 to 6 carbon atoms, branched divalent aliphatic hydrocarbon groups having 3 to 6 carbon atoms, cyclic divalent hydrocarbon groups having 3 to 6 carbon atoms and divalent aromatic hydrocarbon groups having 6 to 20 carbon atoms which may have been substituted with an alkyl group or the like are preferred.

Specific examples of the divalent aliphatic hydrocarbon groups and the cyclic divalent hydrocarbon groups include a methylene group, an ethylene group, a propylene group, a butylene group, a pentylene group, a hexylene group, an isopropylene group, an isobutylene group, a dimethylpropylene group, a cyclopropylene group, a cyclobutylene group, a cyclopentylene group and a cyclohexylene group.

Specific examples of the divalent aromatic hydrocarbon groups having 6 to 20 carbon atoms include a phenylene group, a naphthylene group, an anthrylene group, a dimethylphenylene group, a trimethylphenylene group, an ethylenephenylene group, a diethylenephenylene group, a triethylenephenylene group, a propylenephenylene group, a butylenephenylene group, a methylnaphthylene group, a dimethylnaphthylene group, a trimethylnaphthylene group, a vinylnaphthylene group, an ethenylnaphthylene group, a methylanthrylene group and an ethylanthrylene group.

In the formula (6), R₁₆ represents a hydrogen atom or a methyl group. In one embodiment, R₁₆ is a hydrogen atom. R_{dd} is a linking moiety and has the same meaning as Rₐₐ. In one embodiment, R_{dd} is a phenylene group.

R₁₇ to R₂₃ represent a hydrogen atom or a monovalent organic group having 1 to 20 carbon atoms. In one embodiment, R₁₇ to R₂₃ are each a hydrogen atom.

Preferred examples of the first functional group include an isocyanato group blocked with a blocking agent and an isothiocyanato group blocked with a blocking agent.

The isocyanato group blocked with a blocking agent or the isothiocyanato group blocked with a blocking agent can be produced by reacting a blocking agent having only one active hydrogen atom capable of reacting with an isocyanato group or an isothiocyanato group in a molecule with an isocyanato group or an isothiocyanato group.

As the blocking agent, one which dissociates at a temperature of 170° C. or lower even after reacting with an isocyanato group or an isothiocyanato group is preferred. Examples of the blocking agent include alcohol type compounds, phenol type compounds, active methylene type compounds, mercaptan type compounds, acid amide type compounds, acid imide type compounds, imidazole type compounds, urea type compounds, oxime type compounds, amine type compounds, imine type compounds, bisulfites, pyridine type compounds and pyrazole type compounds. These may be used singly or may be used as a mixture of two or more of them. Preferred are oxime type compounds and pyrazole type compounds.

Specific examples of the blocking agents are as follows. Examples of the alcohol type compounds include methanol, ethanol, propanol, butanol, 2-ethylhexanol, methylcellosolve, butylcellosolve, methylcarbitol, benzyl alcohol and cyclohexanol. Examples of the phenol type compounds include phenol, cresol, ethylphenol, butylphenol, nonylphenol, dinonylphenol, styrenated phenol and hydroxybenzoic acid esters. Examples of the active methylene type compounds include dimethyl malonate, diethyl malonate, methyl acetoacetate, ethyl acetoacetate and acetylacetone. Examples of the mercaptan type compounds include butyl mercaptan and dodecylmercaptan. Examples of the acid amide type compounds include acetanilide, acetic acid amide, ε-caprolactam, δ-valerolactam and γ-butyrolactam, and examples of the acid imide type compounds include succinimide and maleimide. Examples of the imidazole type compounds include imidazole and 2-methylimidazole. Examples of the urea type compounds include urea, thiourea and ethyleneurea. Examples of the amine type compounds include diphenylamine, aniline and carbazole. Examples of the imine type compounds include ethyleneimine and polyethyleneimine. Examples of the bisulfites include sodium bisulfite. Examples of the pyridine type compounds include 2-hydroxypyridine and 2-hydroxyquinoline. Examples of the oxime type compounds include formaldoxime, acetoaldoxime, acetoxime, methylethylketoxime and cyclohexanone oxime. Examples of the pyrazole type compounds include 3,5-dimethylpyrazole and 3,5-diethylpyrazole.

As the isocyanato group blocked with a blocking agent or the isothiocyanato group blocked with a blocking agent which may be used in the present invention, a group represented by the formula (3) or a group represented by the formula (4) is preferred.

In the formula (3) and the formula (4), X′ represents an oxygen atom or a sulfur atom, and R₃ to R₇ are the same or different and represent a hydrogen atom or a monovalent organic group having 1 to 20 carbon atoms. The definition, specific examples and the like of the monovalent organic group are the same as those of the monovalent organic group.

In one embodiment, R₃ and R₄ are the same or different and are groups selected from the group consisting of a methyl group and an ethyl group. Further, in another embodiment, R₅ to R₇ are each a hydrogen atom.

Examples of the isocyanato group blocked with a blocking agent include an O-(methylideneamino)carboxyamino group, an O-(1-ethylideneamino)carboxyamino group, an O-(1-methylethylideneamino)carboxyamino group, an O-[1-methylpropylideneamino]carboxyamino group, an (N-3,5-dimethylpyrazolylcarbonyl)amino group, an (N-3-ethyl-5-methylpyrazolylcarbonyl)amino group, an (N-3,5-diethylpyrazolylcarbonyl)amino group, an (N-3-propyl-5-methylpyrazolylcarbonyl)amino group and an (N-3-ethyl-5-propylpyrazolylcarbonyl)amino group.

Examples of the isothiocyanato group blocked with a blocking agent include an O-(methylideneamino)thiocarboxyamino group, an O-(1-ethylideneamino)thiocarboxyamino group, an O-(1-methylethylideneamino)thiocarboxyamino group, an O-[1-methylpropylideneamino]thiocarboxyamino group, an (N-3,5-dimethylpyrazolylthiocarbonyl)amino group, an (N-3-ethyl-5-methylpyrazolylthiocarbonyl)amino group, an (N-3,5-diethylpyrazolylthiocarbonyl)amino group, an (N-3-propyl-5-methylpyrazolylthiocarbonyl)amino group and an (N-3-ethyl-5-propylpyrazolylthiocarbonyl)amino group.

An isocyanato group blocked with a blocking agent is preferred as the first functional group.

The macromolecular compound (A) can be produced by, for example, a method of copolymerizing a polymerizable monomer which serves as a raw material of a repeating unit represented by the formula (1), a polymerizable monomer which serves as a raw material of a repeating unit represented by the formula (2) and a polymerizable monomer containing a first functional group using a photopolymerization initiator or a thermal polymerization initiator, a method of copolymerizing a polymerizable monomer which serves as a raw material of a repeating unit represented by the formula (1), a polymerizable monomer which serves as a raw material of a repeating unit represented by the formula (5) and a polymerizable monomer containing a first functional group using a photopolymerization initiator or a thermal polymerization initiator, or a method of copolymerizing a polymerizable monomer which serves as a raw material of a repeating unit represented by the formula (1), a polymerizable monomer which serves as a raw material of a repeating unit represented by the formula (6) and a polymerizable monomer containing a first functional group using a photopolymerization initiator or a thermal polymerization initiator.

Examples of the polymerizable monomer which serves as a raw material of a repeating unit represented by the formula (1) include 2-trifluoromethylstyrene, 3-trifluoromethylstyrene, 4-trifluoromethylstyrene, 2,3,4,5,6-pentafluorostyrene and 4-fluorostyrene.

Examples of the polymerizable monomer which serves as a raw material of a repeating unit represented by the formula (2) include 3-chloromethylstyrene, 4-chloromethylstyrene, 3-bromomethylstyrene and 4-bromomethylstyrene.

Examples of the polymerizable monomer which serves as a raw material of a repeating unit represented by the formula (5) include vinyl cinnamate, cinnamyl methacrylate, cinnamoyloxybutyl methacrylate and cinnamyliminoxyiminoethyl methacrylate.

Examples of the polymerizable monomer which serves as a raw material of a repeating unit represented by the formula (6) include phenylvinyl styryl ketone and phenyl(methacryloyloxystyryl)ketone.

Examples of the polymerizable monomer containing the first functional group include monomers having, in their molecules, an isocyanato group blocked with a blocking agent or an isothiocyanato group blocked with a blocking agent, and an unsaturated bond. The monomers having, in their molecules, an isocyanato group blocked with a blocking agent or an isothiocyanato group blocked with a blocking agent, and an unsaturated bond can be produced by reacting a compound having, in its molecule, an isocyanato group or an isothiocyanato group and an unsaturated bond with a blocking agent. An unsaturated double bond is preferred as the unsaturated bond.

Examples of the compound having an unsaturated double bond and an isocyanato group in its molecule include 2-acryloyloxyethylisocyanate. 2-methacryloyloxyethylisocyanate and 2-(2′-methacryloyloxyethyl)oxyethylisocyanate. Examples of the compound having an unsaturated double bond and an isothiocyanato group in its molecule include 2-acryloyloxyethylisothiocyanate, 2-methacryloyloxyethylisothiocyanate and 2-(2′-methacryloyloxyethyl)oxyethylisothiocyanate.

The above-mentioned blocking agents can be suitably used as the blocking agent contained in the polymerizable monomer. In the production of the monomers having, in their molecules, an isocyanato group blocked with a blocking agent or an isothiocyanato group blocked with a blocking agent, and an unsaturated bond, an organic solvent, a catalyst and the like can be added as required.

Examples of the monomer having, in its molecule, an isocyanato group blocked with a blocking agent and an unsaturated double bond include
2-[O-[1′-methylpropylideneamino]carboxyamino]ethyl methacrylate and
2-[N-[1′,3′-dimethylpyrazolyl]carbonylamino]ethyl methacrylate.

Examples of the monomer having, in its molecule, an isothiocyanato group blocked with a blocking agent and an unsaturated double bond include
2-[O-[1′-methylpropylideneamino]thiocarboxyamino]ethyl methacrylate and
2-[N-[1′,3′-dimethylpyrazolyl]thiocarbonylamino]ethyl methacrylate.

Examples of the photopolymerization initiator include carbonyl compounds such as acetophenone, 2,2-dimethoxy-2-phenylacetophenone, 2,2-diethoxyacetophenone, 4-isopropyl-2-hydroxy-2-methylpropiophenone, 2-hydroxy-2-methylpropiophenone, 4,4′-bis(diethylamino)benzophenone, benzophenone, methyl(o-benzoyl)benzoate, 1-phenyl-1,2-propanedione-2-(O-ethoxycarbonyl)oxime, 1-phenyl-1,2-propanedione-2-(o-benzoyl)oxime, benzoin, benzoin methyl ether, benzoin ethyl ether, benzoin isopropyl ether, benzoin isobutyl ether, benzoin octyl ether, benzyl, benzyl dimethyl ketal, benzyl diethyl ketal, diacetyl and the like; derivatives of anthraquinone or thioxanthone such as methylanthraquinone, chloroanthraquinone, chlorothioxanthone, 2-methylthioxanthone, 2-isopropylthioxanthone and the like; and sulfur compounds such as diphenyldisulfide, dithiocarbamate and the like.

When optical energy is used as energy for initiating copolymerization, a wavelength of light with which the polymerizable monomer is irradiated is 360 nm or more and preferably 360 nm to 450 nm.

The thermal polymerization initiator may be any compound which can serve as an initiator of radical polymerization, and examples thereof include azo type compounds such as 2,2′-azobisisobutyronitrile, 2,2′-azobisisovaleronitrile, 2,2′-azobis(2,4-dimethylvaleronitrile), 4,4′-azobis(4-cyanovaleric acid), 1,1′-azobis(cyclohexanecarbonitrile), 2,2′-azobis(2-methylpropane), 2,2′-azobis(2-methylpropionamidine) dihydrochloride and the like; Ketone peroxides such as methyl ethyl ketone peroxide, methyl isobutyl ketone peroxide, cyclohexanone peroxide, acetylacetone peroxide and the like; diacyl peroxides such as isobutyl peroxide, benzoyl peroxide, 2,4-dichlorobenzoyl peroxide, o-methylbenzoyl peroxide, lauroyl peroxide, p-chlorobenzoyl peroxide and the like; hydroperoxides such as 2,4,4-trimethylpentyl-2-hydroperoxide, diisopropylbenzene hydroperoxide, cumene hydroperoxide, tert-butyl hydroperoxide and the like; dialkyl peroxides such as dicumyl peroxide, tert-butylcumyl peroxide, di-tert-butyl peroxide, tris (tert-butyl peroxy)triazine and the like; peroxyketals such as 1,1-di-tert-butylperoxycyclohexane, 2,2-di(tert-butylperoxy)butane and the like; alkyl peresters such as tert-butyl peroxypivalate, tert-butyl peroxy-2-ethylhexanoate, tert-butyl peroxyisobutylate, di-tert-butyl peroxyhexahydroterephthalate, di-tert-butyl peroxyazelate, tert-butyl peroxy-3,5,5-trimethylhaxonoate, tert-butyl peroxyacetate, tert-butyl peroxybenzoate, di-tert-butyl peroxytrimethyladipate and the like; and peroxycarbonates such as diisopropyl peroxydicarbonate, di-sec-butyl peroxydicarbonate, tert-butyl peroxyisopropylcarbonate and the like.

The macromolecular compound (A) used for the present invention may also be produced by adding, at the time of polymerization, a polymerizable monomer other than the polymerizable monomer which serves as a raw material of a repeating unit represented by the formula (1), the polymerizable monomer which serves as a raw material of a repeating unit represented by the formula (2), the polymerizable monomer which serves as a raw material of a repeating unit represented by the formula (5) and the polymerizable monomer containing the first functional group.

Examples of the polymerizable monomer to be used additionally include acrylates and derivatives thereof, methacrylates and derivatives thereof, styrene and derivatives thereof, vinyl acetate and derivatives thereof, methacrylonitrile and derivatives thereof, acrylonitrile and derivatives thereof, vinyl esters of organic carboxylic acids and derivatives thereof, allyl esters of organic carboxylic acids and derivatives thereof, dialkyl esters of fumaric acid and derivatives thereof, dialkyl esters of maleic acid and derivatives thereof, dialkyl esters of itaconic acid and derivatives thereof, N-vinylamide derivatives of organic carboxylic acids, maleimide and derivatives thereof, terminal unsaturated hydrocarbons and derivatives thereof, organic germanium derivatives containing an unsaturated hydrocarbon group, and the like.

The kind of the polymerizable monomer to be used additionally is appropriately selected dependent on the property required of an insulating layer. From the viewpoint of excellent solvent resistance or reduced hysteresis of an organic thin film transistor, a monomer which forms a hard film having a high molecular density in a film containing a compound derived from the monomer like styrene and styrene derivatives is selected. Further, from the viewpoint of adhesiveness to a surface adjacent to an insulating layer such as the surface of a gate electrode or a substrate or the like, a monomer, which imparts plasticity to the macromolecular compound (A) as with methacrylates and derivatives thereof and acrylates and derivatives thereof, is selected. In one preferable embodiment, a monomer having no active hydrogen-containing group is selected.

For example, by using, for a reaction, the polymerizable monomer which serves as a raw material of a repeating unit represented by the formula (1), the polymerizable monomer which serves as a raw material of a repeating unit represented by the formula (2) and the polymerizable monomer containing the first functional group in combination with styrene or a styrene derivative having no active hydrogen-containing group, a gate insulating layer which is particularly high in durability and is small in hysteresis can be obtained.

Also by using, for a reaction, the polymerizable monomer which serves as a raw material of a repeating unit represented by the formula (1), the polymerizable monomer which serves as a raw material of a repeating unit represented by the formula (5) and the polymerizable monomer containing the first functional group in combination with styrene or a styrene derivative having no active hydrogen-containing group, a gate insulating layer which is particularly high in durability and is small in hysteresis can be obtained.

As the acrylates and derivatives thereof, there can be used monofunctional acrylates and multifunctional acrylates whose used amount is limited, and examples thereof include methyl acrylate, ethyl acrylate, n-propylacrylate, isopropyl acrylate, n-butyl acrylate, isobutyl acrylate, sec-butyl acrylate, hexyl acrylate, octylacrylate, 2-ethylhexylacrylate, decylacrylate, isobornyl acrylate, cyclohexyl acrylate, phenyl acrylate, benzyl acrylate, 2-hydroxyethyl acrylate, 2-hydroxypropyl acrylate, 3-hydroxypropyl acrylate, 2-hydroxybutyl acrylate, 2-hydroxyphenylethyl acrylate, ethylene glycol diacrylate, propylene glycol diacrylate, 1,4-butanediol diacrylate, diethylene glycol diacrylate, triethylene glycol diacrylate, trimethylolpropane diacrylate, trimethylolpropane triacrylate, pentaerythritolpentaacrylate, 2,2,2-trifluoroethylacrylate, 2,2,3,3,3-pentafluoropropyl acrylate, 2-(perfluorobutyl)ethyl acrylate, 3-(perfluorobutyl)-2-hydroxypropyl acrylate, 2-(perfluorohexyl)ethyl acrylate, 3-(perfluorohexyl)-2-hydroxypropyl acrylate, 2-(perfluorooctyl)ethyl acrylate, 3-(perfluorooctyl)-2-hydroxypropyl acrylate, 2-(perfluorodecyl)ethyl acrylate, 2-(perfluoro-3-methylbutyl)ethyl acrylate, 3-(perfluoro-3-methylbutyl)-2-hydroxypropyl acrylate, 2-(perfluoro-5-methylhexyl)ethyl acrylate, 2-(perfluoro-3-methylbutyl)-2-hydroxypropyl acrylate, 3-(perfluoro-5-methylhexyl)-2-hydroxypropyl acrylate, 2-(perfluoro-7-methyloctyl)ethyl acrylate, 3-(perfluoro-7-methyloctyl)-2-hydroxypropyl acrylate, 1H,1H,3H-tetrafluoropropyl acrylate, 1H,1H,5H-octafluoropentyl acrylate, 1H,1H,7H-dodecafluoroheptyl acrylate, 1H,1H,9H-hexadecafluorononyl acrylate, 1H-1-(trifluoromethyl)trifluoroethyl acrylate, 1H,1H,3H-hexafluorobutyl acrylate, N,N-dimethylacrylamide, N,N-diethylacrylamide and N-acryloylmorpholine.

As the methacrylates and derivatives thereof, there can be used monofunctional methacrylates and multifunctional methacrylates whose used amount is limited, and examples thereof include methyl methacrylate, ethyl methacrylate, n-propyl methacrylate, isopropyl methacrylate, n-butyl methacrylate, isobutyl methacrylate, sec-butyl methacrylate, hexyl methacrylate, octyl methacrylate, 2-ethylhexyl methacrylate, decyl methacrylate, isobornyl methacrylate, cyclohexyl methacrylate, phenyl methacrylate, benzyl methacrylate, 2-hydroxyethyl methacrylate, 2-hydroxypropyl methacrylate, 3-hydroxypropyl methacrylate, 2-hydroxybutyl methacrylate, 2-hydroxyphenylethyl methacrylate, ethylene glycol dimethacrylate, propylene glycol dimethacrylate, 1,4-butanediol dimethacrylate, diethyleneglycol dimethacrylate, triethylene glycol dimethacrylate, trimethylolpropane dimethacrylate, trimethylolpropane trimethacrylate, pentaerythritol pentamethacrylate, 2,2,2-trifluoroethyl methacrylate, 2,2,3,3,3-pentafluoropropyl methacrylate, 2-(perfluorobutyl)ethyl methacrylate, 3-(perfluorobutyl)-2-hydroxypropyl methacrylate, 2-(perfluorohexyl)ethyl methacrylate, 3-(perfluorohexyl)-2-hydroxypropyl methacrylate, 2-(perfluorooctyl)ethyl methacrylate, 3-(perfluorooctyl)-2-hydroxypropyl methacrylate, 2-(perfluorodecyl)ethyl methacrylate, 2-(perfluoro-3-methylbutyl)ethyl methacrylate, 3-(perfluoro-3-methylbutyl)-2-hydroxypropyl methacrylate, 2-(perfluoro-5-methylhexyl)ethyl methacrylate, 2-(perfluoro-3-methylbutyl)-2-hydroxypropyl methacrylate, 3-(perfluoro-5-methylhexyl)-2-hydroxypropyl methacrylate, 2-(perfluoro-7-methyloctyl)ethyl methacrylate, 3-(perfluoro-7-methyloctyl)-2-hydroxypropyl methacrylate, 1H,1H,3H-tetrafluoropropyl methacrylate, 1H,1H,5H-octafluoropentyl methacrylate, 1H,1H,7H-dodecafluoroheptyl methacrylate, 1H,1H,9H-hexadecafluorononyl methacrylate, 1H-1-(trifluoromethyl)trifluoroethyl methacrylate, 1H,1H,3H-hexafluorobutyl methacrylate, N,N-dimethylmethacrylamide, N,N-diethylmethacrylamide and N-acryloylmorpholine.

Examples of styrene and derivatives thereof include styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, o-chlorostyrene, m-chlorostyrene, p-chlorostyrene, o-bromostyrene, m-bromostyrene, p-bromostyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,4-dimethyl-α-methylstyrene, 2,3-dimethyl-α-methylstyrene, 3,5-dimethyl-α-methylstyrene, p-isopropyl-α-methylstyrene, α-ethylstyrene, α-chlorostyrene, divinylbenzene, divinylbiphenyl, diisopropylbenzene and 4-aminostyrene.

Examples of the vinyl esters of organic carboxylic acids and derivatives thereof include vinyl acetate, vinyl propionate, vinyl butyrate, vinyl benzoate and divinyl adipate.

Examples of the allyl esters of organic carboxylic acids and derivatives thereof include allyl acetate, allyl benzoate, diallyl adipate, diallyl terephthalate, diallyl isophthalate and diallyl phthalate.

Examples of the dialkyl esters of fumaric acid and derivatives thereof include dimethyl fumarate, diethyl fumarate, diisopropyl fumarate, di-sec-butyl fumarate, diisobutyl fumarate, di-n-butyl fumarate, di-2-ethylhexyl fumarate and dibenzyl fumarate.

Examples of the dialkyl esters of maleic acid and derivatives thereof include dimethyl maleate, diethyl maleate, diisopropyl maleate, di-sec-butyl maleate, diisobutyl maleate, di-n-butyl maleate, di-2-ethylhexyl maleate and dibenzyl maleate.

Examples of the dialkyl esters of itaconic acid and derivatives thereof include dimethyl itaconate, diethyl itaconate, diisopropyl itaconate, di-sec-butyl itaconate, di-isobutyl itaconate, di-n-butyl itaconate, di-2-ethylhexyl itaconate and dibenzyl itaconate.

Examples of the N-vinylamide derivatives of organic carboxylic acids include N-methyl-N-vinylacetamide.

Examples of maleimide and derivatives thereof include N-phenylmaleimide and N-cyclohexylmaleimide.

Examples of the terminal unsaturated hydrocarbons and derivatives thereof include 1-butene, 1-pentene, 1-hexene, 1-octene, vinylcyclohexane, vinyl chloride and allyl alcohol.

Examples of the organic germanium derivatives containing an unsaturated hydrocarbon group include allyltrimethylgermanium, allyltriethylgermanium, allyltributylgermanium, trimethylvinylgermanium and triethylvinylgermanium.

Among these, alkyl acrylates, alkyl methacrylates, styrene, acrylonitrile, methacrylonitrile and allyltrimethylgermanium are preferred.

The used amount of the polymerizable monomer which serves as a raw material of a repeating unit represented by the formula (1) is adjusted so that the amount of fluorine to be introduced into the macromolecular compound (A) may become appropriate.

The amount of fluorine to be introduced into the macromolecular compound (A) is preferably 1 to 80% by mass, more preferably 5 to 70% by mass, and further preferably 10 to 60% by mass based on the mass of the macromolecular compound (A). When the amount of fluorine is less than 1% by mass, the effect of reducing the hysteresis of an electric field effect type organic thin film transistor may become insufficient, and when it exceeds 80% by mass, the affinity with an organic semiconductor material deteriorates so that it may become difficult to laminate an active layer thereon.

The molar ratio of the charged monomer having, in its molecule, an unsaturated double bond and an isocyanato group blocked with a blocking agent or an isothiocyanato group blocked with a blocking agent to all the monomers which are involved in any polymerization is preferably 5 mol % or more and 50 mol % or less, and more preferably 5 mol % or more and 40 mol % or less. By adjusting the molar ratio of the charged monomer within this range, a cross-linked structure is formed sufficiently inside an insulating layer, the content of polar groups is maintained at a low level, and the polarization of an insulating layer is inhibited.

The macromolecular compound (A) preferably has a weight average molecular weight of 3000 to 1000000, more preferably a weight average molecular weight of 5000 to 500000, and it may be linear, branched or cyclic.

The repeating unit represented by the formula (1), the repeating unit represented by the formula (2), the repeating unit represented by the formula (5) and the repeating unit represented by the formula (6), which compose the macromolecular compound (A), do not have any active hydrogen-containing group like a hydroxyl group in their repeating units. Therefore, it is thought that a gate insulating layer to be formed is low in polarity and the polarization of the gate insulating layer is inhibited. If the polarization of a gate insulating layer is inhibited, the hysteresis of an electric field effect type organic thin film transistor is lowered and operation accuracy is improved.

Examples of macromolecular compounds used for the present invention containing a repeating unit represented by the formula (1) and a repeating unit represented by the formula (2) and containing, in their molecules, two or more first functional groups that generate second functional groups which react with active hydrogen by electromagnetic waves or heat include poly(styrene-co-3-chloromethylstyrene-co-pentafluorostyrene-co-[2-[O-(1′-methylpropylideneamino)carboxyamino]ethyl-methacrylate]), poly(styrene-co-3-chloromethylstyrene-co-pentafluorostyrene-co-[2-[1′-(3′,5′-dimethylpyrazolyl)carbonylamino]ethyl-methacrylate]), poly(styrene-co-3-chloromethylstyrene-co-pentafluorostyrene-co-acrylonitrile-co-[2-[O-(1′-methylpropylideneamino)carboxyamino]ethyl-methacrylate]), poly(styrene-co-3-chloromethylstyrene-co-pentafluorostyrene-co-acrylonitrile-co-[2-[1′-(3′,5′-dimethylpyrazolyl)carbonylamino]ethyl-methacrylate]), poly(styrene-co-3-chloromethylstyrene-co-pentafluorostyrene-co-acrylonitrile-co-[2-[O-(1′-methylpropylideneamino)carboxyamino]ethyl-methacrylate]-co-allyltrimethylgermanium), poly(styrene-co-3-chloromethylstyrene-co-pentafluorostyrene-co-acrylonitrile-co-[2-[1′-(3′,5′-dimethylpyrazolyl)carbon ylamino]ethyl-methacrylate]-co-allyltrimethylgermanium), poly(3-chloromethylstyrene-co-pentafluorostyrene-co-[2-[O-(1′-methylpropylideneamino)carboxyamino]ethyl-methacrylate]), poly(3-chloromethylstyrene-co-pentafluorostyrene-co-[2-[1′-(3′,5′-dimethylpyrazolyl)carbonylamino]ethyl-methacrylate]), poly(styrene-co-4-chloromethylstyrene-co-[2-[O-(1′-methylpropylideneamino)carboxyamino]ethyl-methacrylate]), poly(styrene-co-4-chloromethylstyrene-co-[2-[1′-(3′,5′-dimethylpyrazolyl)carbonylamino]ethyl-methacrylate]) and poly(styrene-co-3-chloromethylstyrene-co-4-chloromethylstyrene-co-pentafluorostyrene-co-[2-[O-(1′-methylpropylideneamino)carboxyamino]ethyl-methacrylate]).

Examples of macromolecular compounds used for the present invention containing a repeating unit represented by the formula (1) and a repeating unit represented by the formula (5) and containing, in their molecules, two or more first functional groups that generate second functional groups which react with active hydrogen by electromagnetic waves or heat include poly(styrene-co-vinylcinnamate-co-pentafluorostyrene-co-[2-[O-(1′-methylpropylideneamino)carboxyamino]ethyl-methacrylate]), poly(styrene-co-vinylcinnamate-co-pentafluorostyrene-co-[2-[1′-(3′,5′-dimethylpyrazolyl)carboxyamino]ethyl-methacrylate]), poly(styrene-co-vinylcinnamate-co-pentafluorostyrene-co-acrylonitrile-co-[2-[O-(1′-methylpropylideneamino)carboxyamino]ethyl-methacrylate]), poly(styrene-co-vinylcinnamate-co-pentafluorostyrene-co-acrylonitrile-co-[2-[1′-(3′,5′-dimethylpyrazolyl)carboxyamino]ethyl-methacrylate]), poly(styrene-co-vinylcinnamate-co-pentafluorostyrene-co-acrylonitrile-co-[2-[O-(1′-methylpropylideneamino)carboxyamino]ethyl-methacrylate]-co-allyltrimethylgermanium), poly(styrene-co-vinylcinnamate-co-pentafluorostyrene-co-acrylonitrile-co-[2-[1′-(3′,5′-dimethylpyrazolyl)carboxyamino]ethyl-methacrylate]-co-allyltrimethylgermanium), poly(vinylcinnamate-co-pentafluorostyrene-co-[2-[0-(1′-meth ylpropylideneamino)carboxyamino]ethyl-methacrylate]), poly(vinylcinnamate-co-pentafluorostyrene-co-[2-[1′-(3′,5′-dimethylpyrazolyl)carboxyamino]ethyl-methacrylate]), poly(styrene-co-vinylcinnamate-co-[2-[O-(1′-methylpropylideneamino)carboxyamino]ethyl-methacrylate]), poly(styrene-co-vinylcinnamate-co-[2-[1′-(3′,5′-dimethylpyrazolyl)carboxyamino]ethyl-methacrylate]) and poly(styrene-co-vinylcinnamate-co-4-chloromethylstyrene-co-pentafluorostyrene-co-[2-[O-(1′-methylpropylideneamino)carboxyamino]ethyl-methacrylate]).

Examples of macromolecular compounds used for the present invention containing a repeating unit represented by the formula (1) and a repeating unit represented by the formula (6) and containing, in their molecules, two or more first functional groups that generate second functional groups which react with active hydrogen by electromagnetic waves or heat include poly(styrene-co-phenylvinyl styryl ketone-co-pentafluorostyrene-co-[2-[O-(1′-methylpropylidene amino)carboxyamino]ethyl-methacrylate]), poly(styrene-co-phenylvinyl styryl ketone-co-pentafluorostyrene-co-[2-[1′-(3′,5′-dimethylpyrazolyl)carboxyamino]ethyl-methacrylate]), poly(styrene-co-phenylvinyl styryl ketone-co-pentafluorostyrene-co-acrylonitrile-co-[2-[O-(1′-methylpropylideneamino)carboxyamino]ethyl-methacrylate]), poly(styrene-co-phenylvinyl styryl ketone-co-pentafluorostyrene-co-acrylonitrile-co-[2-[1′-(3′,5′-dimethylpyrazolyl)carboxyamino]ethyl-methacrylate]), poly(styrene-co-phenylvinyl styryl ketone-co-pentafluorostyrene-co-acrylonitrile-co-[2-[O-(1′-methylpropylideneamino)carboxyamino]ethyl-methacrylate]-co-allyltrimethylgermanium), poly(styrene-co-phenylvinyl styrylketone-co-pentafluorostyrene-co-acrylonitrile-co-[2-[1′-(3′,5′-dimethylpyrazolyl)carboxyamino]ethyl-methacrylate]-co-allyltrimethylgermanium), poly(phenylvinyl styryl ketone-co-pentafluorostyrene-co-[2-[O-(1′-methylpropylidene amino) carboxyamino]ethyl-methacrylate]), poly(phenylvinyl styryl ketone-co-pentafluorostyrene-co-[2-[1′-(3′,5′-dimethylpyrazolyl)carboxyamino]ethyl-methacrylate]), poly(styrene-co-phenylvinyl styryl ketone-co-[2-[O-(1′-methylpropylideneamino)carboxyamino]ethyl-methacrylate]), polystyrene-co-phenylvinyl styryl ketone-co-[2-[1′-(3′,5′-dimethylpyrazolyl)carboxyamino]ethyl-methacrylate]), poly(styrene-co-phenylvinyl styryl ketone-co-4-chloromethylstyrene-co-pentafluorostyrene-co-[2-[O-(1′-methylpropylideneamino)carboxyamino]ethyl-methacrylate]), poly(styrene-co-phenyl(methacryloyloxystyryl)ketone-co-pentafluorostyrene-co-[2-[O-(1′-methylpropylidene amino)carboxyamino]ethyl-methacrylate]), poly(styrene-co-phenyl(methacryloyloxystyryl)ketone-co-pentafluorostyrene-co-[2-[1′-(3′,5′-dimethylpyrazolyl)carboxyamino]ethyl-methacrylate]), poly(styrene-co-phenyl(methacryloyloxystyryl)ketone-co-pentafluorostyrene-co-acrylonitrile-co-[2-[O-(1′-methylpropylideneamino)carboxyamino]ethyl-methacrylate]), poly(styrene-co-phenyl(methacryloyloxystyryl)ketone-co-pentafluorostyrene-co-acrylonitrile-co-[2-[1′-(3′,5′-dimethylpyrazolyl)carboxyamino]ethyl-methacrylate]), poly(styrene-co-phenyl(methacryloyloxystyryl)ketone-co-pentafluorostyrene-co-acrylonitrile-co-[2-[0-(1′-methylpropylideneamino)carboxyamino]ethyl-methacrylate]-co-allyltrimethylgermanium), poly(styrene-co-phenyl(methacryloyloxystyryl)ketone-co-pentafluorostyrene-co-acrylonitrile-co-[2-[1′-(3′,5′-dimethylpyrazolyl)carboxyamino]ethyl-methacrylate]-co-allyltrimethylgermanium), poly(phenyl(methacryloyloxystyryl)ketone-co-pentafluorostyrene-co-[2-[O-(1′-methylpropylidene amino) carboxyamino]ethyl-methacrylate]), poly(phenyl(methacryloyloxystyryl)ketone-co-pentafluorostyrene-co-[2-[1′-(3′,5′-dimethylpyrazolyl)carboxyamino]ethyl-methacrylate]), poly(styrene-co-phenyl(methacryloyloxystyryl)ketone-co-[2-[O-(1′-methylpropylideneamino)carboxyamino]ethyl-methacrylate]), poly(styrene-co-phenyl(methacryloyloxystyryl) ketone-co-[2-[1′-(3′,5′-dimethylpyrazolyl)carboxyamino]ethyl-methacrylate]) and poly(styrene-co-phenyl(methacryloyloxystyryl)ketone-co-4-chloromethylstyrene-co-pentafluorostyrene-co-[2-[O-(1′-methylpropylideneamino)carboxyamino]ethyl-methacrylate]).

From the viewpoint of reducing an absolute value of threshold voltage, the number of the repeating units represented by the formula (1) of the macromolecular compound (A) is preferably 30 to 80 in the case where the number of the repeating units of the macromolecular compound (A) is taken as 100.

### Active Hydrogen Compound (B)

The active hydrogen compound (B) is a low-molecular compound containing two or more active hydrogen atoms in its molecule or a macromolecular compound containing two or more active hydrogen atoms in its molecule. Typical examples of active hydrogen include hydrogen atoms contained in an amino group, a hydroxyl group, or a mercapto group. Hydrogen atoms contained in the above-mentioned reactive functional groups, especially, hydrogen atoms contained in a phenolic hydroxyl group which can well cause a reaction with an isocyanato group or an isothiocyanato group, hydrogen atoms contained in an alcoholic hydroxyl group and hydrogen atoms contained in an aromatic amino group are suitable as active hydrogen.

Specific examples of the low-molecular compound containing two or more active hydrogen atoms in its molecule include compounds each having a structure in which two or more active hydrogen-containing groups are attached to a low-molecular (monomer) structure. Examples of the low-molecular structure include an alkyl structure and a benzene ring structure. Specific examples of the low-molecular compound include amine type compounds, alcohol type compounds, phenol type compounds and thiol type compounds.

Examples of the amine type compounds include ethylenediamine, propylenediamine, hexamethylenediamine, N,N,N′,N′-tetraminoethylethylenediamine, ortho-phenylenediamine, meta-phenylenediamine, para-phenylenediamine, N,N′-diphenyl-p-phenylenediamine, melamine, 2,4,6-triaminopyrimidine, 1,5,9-triazacyclododecane, 1,3-bis(3-aminopropyl)tetramethyldisiloxane, 1,4-bis(3-aminopropyldimethylsilyl)benzene and 3-(2-aminoethylaminopropyl)tris(trimethylsiloxy)silane.

Examples of the alcohol type compounds include ethylene glycol, 1,2-dihydroxypropane, glycerol and 1,4-dimethanolbenzene.

Examples of the phenol type compounds include 1,2-dihydroxybenzene, 1,3-dihydroxybenzene, 1,4-dihydroxybenzene (hydroquinone), 1,2-dihydroxynaphthalene, resorcinol, fluoroglycerol, 2,3,4-trihydroxybenzaldehyde and 3,4,5-trihydroxybenzamide.

Examples of the thiol type compounds include ethylene dithiol and para-phenylene dithiol.

As the low-molecular compound containing two or more active hydrogen atoms in its molecule, the alcohol type compounds, the phenol type compounds and the aromatic amine type compounds are preferred.

On the other hand, in the macromolecular compound containing two or more active hydrogen atoms in its molecule, the active hydrogen may be bound directly to a main chain constituting the macromolecular compound or may be bound through a prescribed group. Moreover, the active hydrogen may be contained in structural units constituting a macromolecular compound, and in such a case, the active hydrogen may be contained in every structural unit or may be contained only in some structural units. Furthermore, the active hydrogen may be bound only to terminals of a macromolecular compound.

Specific examples of the macromolecular compound containing two or more active hydrogen atoms in its molecule include compounds each having a structure in which two or more active hydrogen-containing groups are bound to a macromolecular (polymer) structure. Such a macromolecular compound is obtained by forming a polymer by polymerizing a monomer having an active hydrogen-containing group and an unsaturated bond such as a double bond in its molecule singly, or by copolymerizing such a monomer with a polymerizable monomer which serves as a raw material of a repeating unit represented by the formula (2), (5) or (6), or by copolymerizing the above-mentioned monomer with other copolymerizable compounds. A photopolymerization initiator or a thermal polymerization initiator may be used in such polymerization. As the polymerizable monomer, the photopolymerization initiator and the thermal polymerization initiator, the same substances as those described above can be used.

Examples of the monomer having an active hydrogen-containing group and an unsaturated bond in its molecule include aminostyrene, hydroxystyrene, vinylbenzyl alcohol, aminoethyl methacrylate, ethylene glycol monovinyl ether and 4-hydroxybutyl acrylate.

As the monomer having an active hydrogen-containing group and an unsaturated bond in its molecule, a monomer having a hydroxyl group in its molecule is preferred.

A novolac resin obtained by condensing a phenol compound and formaldehyde in the presence of an acid catalyst is also suitably used as the macromolecular compound containing two or more active hydrogen atoms in its molecule.

A polystyrene-equivalent weight average molecular weight of a macromolecular compound containing two or more active hydrogen-containing groups in its molecule is preferably 1000 to 1000000, and more preferably 3000 to 500000. Thereby, it becomes possible to achieve the effect of improving the planarity and the uniformity of an insulating layer. The polystyrene-equivalent weight average molecular weight measured by GPC.

### Organic Thin Film Transistor Insulating Layer Material

An organic thin film transistor insulating layer material is obtained by mixing the macromolecular compound (A) and the active hydrogen compound (B). The mixing proportion of the two compounds is adjusted in such a way that the molar ratio of the second functional group generated by irradiating the macromolecular compound (A) with electromagnetic waves or by heating the macromolecular compound (A) to the active hydrogen-containing group of the active hydrogen compound (B) is preferably 60/100 to 150/100, more preferably 70/100 to 120/100, and further preferably 90/100 to 110/100. When the ratio is less than 60/100, the amount of the active hydrogen is excessive and therefore the effect of reducing hysteresis may deteriorate, and when it exceeds 150/100, the amount of functional groups which react with the active hydrogen is excessive and therefore the absolute value of threshold voltage may increase.

The organic thin film transistor insulating layer material of the present invention may contain, for example, a solvent for mixing a material or adjusting viscosity and an additive used in combination with a cross-linking agent which is used for cross-linking a macromolecular compound (A). The solvent to be used is an ether type solvent such as tetrahydrofuran, diethyl ether or the like, an aliphatic hydrocarbon type solvent such as hexane or the like, an alicyclic hydrocarbon type solvent such as cyclohexane or the like, an unsaturated hydrocarbon type solvent such as pentene or the like, an aromatic hydrocarbon type solvent such as xylene or the like, a ketone type solvent such as acetone or the like, an acetate type solvent such as butyl acetate or the like, an alcohol type solvent such as isopropanol or the like, a halogen type solvent such as chloroform or the like, or a mixed solvent thereof. As the additive, there can be used a catalyst for promoting a cross-linking reaction, a leveling agent, a viscosity modifier and the like.

The organic thin film transistor insulating layer material of the present invention is a composition used for forming an insulating layer included in an organic thin film transistor. The composition is preferably used for forming an overcoat layer or a gate insulating layer among the insulating layers of an organic thin film transistor. The organic thin film transistor insulating layer material is preferably an organic thin film transistor overcoat layer composition or an organic thin film transistor gate insulating layer composition, and more preferably an organic thin film transistor gate insulating layer material.

### Organic Thin Film Transistor

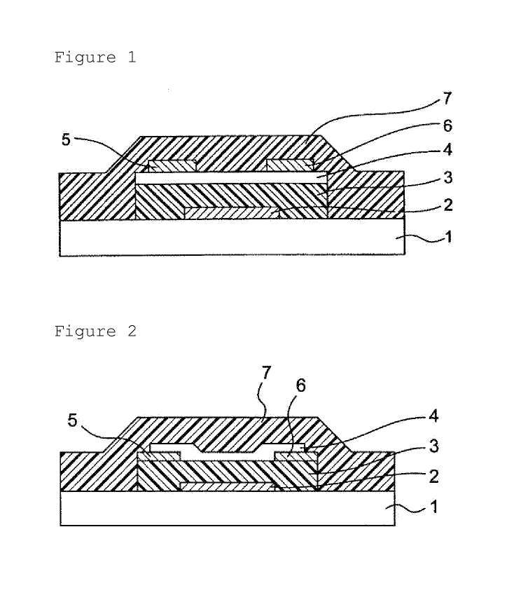

FIG. 1 is a schematic sectional view illustrating the structure of a bottom-gate top-contact type organic thin film transistor which is one embodiment of the present invention. This organic thin film transistor has a substrate 1, a gate electrode 2 formed on the substrate 1, a gate insulating layer 3 formed on the gate electrode 2, an organic semiconductor layer 4 formed on the gate insulating layer 3, a source electrode 5 and a drain electrode 6 formed across a channel portion on the organic semiconductor layer 4 and an overcoat layer 7 covering the whole body of the device.

The bottom-gate top-contact type organic thin film transistor can be produced by, for example, forming a gate electrode on a substrate, forming a gate insulating layer on the gate electrode, forming an organic semiconductor layer on the gate insulating layer, forming a source electrode and a drain electrode on the organic semiconductor layer, and forming an overcoat. The organic thin film transistor insulating layer material of the present invention is suitably used for forming a gate insulating layer as an organic thin film transistor gate insulating layer material. Further, it can also be used for forming an overcoat layer as an organic thin film transistor overcoat layer material.

FIG. 2 is a schematic sectional view illustrating the structure of a bottom-gate bottom contact type organic thin film transistor which is one embodiment of the present invention. This organic thin film transistor has a substrate 1, a gate electrode 2 formed on the substrate 1, a gate insulating layer 3 formed on the gate electrode 2, a source electrode 5 and a drain electrode 6 formed across a channel portion on the gate insulating layer 3, an organic semiconductor layer 4 formed on the source electrode 5 and the drain electrode 6 and an overcoat layer 7 covering the whole body of the device.

The bottom-gate bottom-contact type organic thin film transistor can be produced by, for example, forming a gate electrode on a substrate, forming a gate insulating layer on the gate electrode, forming a source electrode and a drain electrode on the gate insulating layer, forming an organic semiconductor layer on the source electrode and the drain electrode, and forming an overcoat. The organic thin film transistor insulating layer material of the present invention is suitably used for forming a gate insulating layer as an organic thin film transistor gate insulating layer material. Further, it can also be used for forming an overcoat layer as an organic thin film transistor overcoat layer material.

The formation of the gate insulating layer or the overcoat layer is carried out by preparing the application liquid of an insulating layer material, by, if necessary, further adding a solvent or the like to an organic thin film transistor insulating layer material, applying the application liquid onto the surface of a layer located below the gate insulating layer or the overcoat layer and drying it to cure. The organic solvent to be used for the insulating layer application liquid is not particularly restricted if it can dissolve a macromolecular compound and a cross-linking agent and it is preferably an organic solvent having a boiling point under ordinary pressure of from 100° C. to 200° C. Examples of the organic solvent include 2-heptanone (boiling point of 150° C.), propylene glycol monomethyl ether acetate (boiling point of 146° C.) and the like. A leveling agent, a surfactant, a curing catalyst and the like may be added to the insulating layer application liquid as necessary. The organic thin film transistor insulating layer material of the present invention can also be used for forming a gate insulating layer as an organic thin film transistor gate insulating layer composition.

The insulating layer application liquid can be applied onto the gate electrode by a conventional method such as spin coating, a die coater, screen printing, inkjet or the like. The formed applied layer is dried as necessary. The drying herein means removal of the solvent of the resin composition applied.

The applied layer dried is then cured. Curing means that the organic thin film transistor insulating layer material is cross-linked. The cross-linking of the insulating layer material for a transistor is performed, for example, by applying electromagnetic waves or heat to the applied layer. The reason for this is that by doing so, a second functional group is generated from a first functional group of a macromolecular compound (A) and the second functional group reacts with an active hydrogen-containing group of an active hydrogen compound (B).

Otherwise, the cross-linking of the insulating layer material for a transistor is performed, for example, by irradiating the applied layer with light. The reason for this is that by doing so, a photodimerizable group of the macromolecular compound (A) is dimerized by a radical coupling reaction or a cyclization reaction.

It is preferred that the application of electromagnetic waves or heat to the applied layer and the light-irradiation of the applied layer are both performed. The reason for this is that cross-linking density of the insulating layer is enhanced. Consequently, particularly when the applied layer is used as a gate insulating layer, an absolute value of threshold voltage (Vth) and hysteresis of the organic thin film transistor are decreased. It is thought that enhancement of the cross-linking density of an insulating layer inhibits the polarization at the time of applying a voltage more and therefore the absolute value of threshold voltage and the hysteresis of the organic thin film transistor are decreased.

As a method of performing both of the application of electromagnetic waves or heat to the applied layer and the light-irradiation of the applied layer, there is, for example, a method of performing the step of irradiating the applied layer with light or electron beams to dimerize a functional group which absorbs optical energy or electron beam energy to cause a dimerization reaction in a macromolecular compound (A) and then performing the step of applying electromagnetic waves or heat to the applied layer to generate a second functional group from a first functional group of the macromolecular compound (A) and reacting the second functional group with an active hydrogen-containing group of an active hydrogen compound (B).

When heat is applied to the applied layer, the applied layer is heated to a temperature of about 80 to 250° C., and preferably about 100 to 230° C. and maintained at this temperature for about 5 to 120 minutes, and preferably about 10 to 60 minutes. When the heating temperature is too low or when the heating time is too short, the cross-linking of the insulating layer may be insufficient, and when the heating temperature is too high or when the heating time is too long, the insulating layer may be damaged. When electromagnetic waves are applied to the applied layer or when microwaves are applied to the applied layer to heat, conditions of application are adjusted in such a way that the effect of application on the applied layer is equal to that in the case of heating.

When the photodimerizable group is a halomethyl group-substituted aryl group or a halomethyl group-substituted phenyl group, these groups are bound together by irradiation with light or electron beams, preferably ultraviolet light or electron beams. The wavelength of irradiation light is 360 nm or less, and preferably 150 to 300 nm. When the wavelength of irradiation light exceeds 360 nm, the cross-linking of the organic thin film transistor insulating layer material may be insufficient.

When the photodimerizable group is a vinyl group whose hydrogen atom at the 2-position is substituted with an aryl group or a phenyl group or a vinyl group whose hydrogen atom at the 2-position is substituted with an arylcarbonyl group or a phenylcarbonyl group, these groups are bound together by irradiation with light or electron beams, preferably ultraviolet light or electron beams. The wavelength of irradiation light is 400 nm or less, and preferably 150 to 380 nm. When the wavelength of irradiation light exceeds 400 nm, the cross-linking of the organic thin film transistor insulating layer material may be insufficient.

Irradiation of ultraviolet light can be performed, for example, by the use of an exposure apparatus which is in use for the production of semiconductors or a UV lamp which is in use for curing UV-curable resins. Irradiation of electron beams can be performed, for example, by the use of a microminiature electron beam irradiation tube. Heating can be performed by the use of a heater, an oven or the like. Other irradiation conditions and heating conditions are appropriately determined according to the kind, amount and the like of the photodimerizable group.

On the gate insulating layer may be formed a self-organized monomolecular film layer. The self-organized monomolecular film layer can be formed by, for example, treating the gate insulating layer with a solution in which 1 to 10% by weight of an alkylchlorosilane compound or alkylalkoxysilane compound has been dissolved in an organic solvent.

Examples of the alkylchlorosilane compound include methyltrichlorosilane, ethyltrichlorosilane, butyltrichlorosilane, decyltrichlorosilane and octadecyltrichlorosilane.

Examples of the alkylalkoxysilane compound include methyltrimetoxysilane, ethyltrimethoxysilane, butyltrimethoxysilane, decyltrimetoxysilane and octadecyltrimethoxysilane.

The substrate 1, the gate electrode 2, the source electrode 5, the drain electrode 6 and the organic semiconductor layer 4 may be constituted using materials and methods which are used usually. A plate or a film of resin or plastics, a glass plate, a silicon plate or the like is used for the material of the substrate. The electrodes are formed by a publicly known method such as a vacuum deposition method, a sputtering method, a printing method, an inkjet method or the like using chromium, gold, silver, aluminum, molybdenum or the like as their materials.

π-Conjugated polymers are used as an organic semiconductor compound for forming the organic semiconductor layer 4 and, for example, polypyrroles, polythiophenes, polyanilines, polyallylamines, fluorenes, polycarbazoles, polyindoles, and poly(p-phenylenevinylene)s can be used. Moreover, low-molecular substances soluble in organic solvents, e.g., derivatives of polycyclic aromatics such as pentacene, phthalocyanine derivatives, perylene derivatives, tetrathiafulvalene derivatives, tetracyanoquinodimethane derivatives, fullerenes and carbon nanotubes can be used. Specific examples thereof include a condensate of 9,9-di-n-octylfluorene-2,7-di(ethylene boronate) and 5,5′-dibromo-2,2′-bithiophene.

The formation of the organic semiconductor layer is carried out, for example, by adding, if necessary, a solvent or the like to an organic semiconductor compound to prepare an organic semiconductor coating solution, applying the organic semiconductor coating solution onto a gate insulating layer, and drying the coating solution. In the present invention, the resin constituting the gate insulating layer has a benzene ring and has affinity with an organic semiconductor compound. Therefore, a uniform flat interface is formed between an organic semiconductor layer and a gate insulating layer by the above-mentioned application and drying method.

The solvent to be used in the organic semiconductor coating solution is not particularly limited as long as it can dissolve or disperse organic semiconductors, and it is preferably a solvent having a boiling point of 50° C. to 200° C. under ordinary pressure. Examples of the solvent include chloroform, toluene, anisole, 2-heptanone and propylene glycol monomethyl ether acetate. As with the above-mentioned insulating layer coating solution, the organic semiconductor coating solution can be applied onto the gate insulating layer by a publicly known method such as spin coating, a die coater, screen printing, inkjet or the like.

The organic thin film transistor of the present invention may be coated with an overcoat material for the purpose of protecting the organic thin film transistor and improving the smoothness of its surface.

An insulating layer produced by using the organic thin film transistor insulating layer material of the present invention can have a smooth film laminated thereon and can easily form a laminated structure. Moreover, an organic electroluminescence device can be suitably mounted on the insulating layer.

By the use of the organic thin film transistor insulating layer material of the present invention, a member for displays having an organic thin film transistor can be favorably produced. By the use of the member for displays which has an organic thin film transistor, a display having a member for displays can be produced.

The organic thin film transistor insulating layer material of the present invention can also be used for applications for forming a layer contained in a transistor other than an insulating layer and a layer contained in an organic electroluminescence device.

### EXAMPLES

Hereinafter, the present invention will be described by way of examples, but it is needless to say that the present invention is not limited by these examples.

### Synthesis Example 1

In a 50 ml pressure-resistant container (produced by ACE), 3.47 g of styrene (produced by Wako Pure Chemical Industries, Ltd.), 4.85 g of 2,3,4,5,6-pentafluorostyrene (produced by Aldrich Chemical Company, Inc.), 2.54 g of vinylbenzyl chloride (produced by Aldrich Chemical Company, Inc.), 2.00 g of 2-[O-[1′-methylpropylideneamino]carboxyamino]ethyl-methacrylate (produced by Showa Denko K.K., trade name “Karenz MOI-BM”), 0.06 g of 2,2′-azobis(2-methylpropionitrile) and 3.23 g of 2-heptanone (produced by Wako Pure Chemical Industries, Ltd.) were put, the resulting mixture was bubbled with an argon gas, and then the container was stopped tightly. Polymerization was carried out in an oil bath of 60° C. for 20 hours. After the completion of polymerization, 15.99 g of 2-heptanone was added to obtain a viscous 2-heptanone solution containing a macromolecular compound 1 dissolved therein. The macromolecular compound 1 has the following repeating unit. A suffix to a parenthesis indicates mole fraction of a repeating unit.

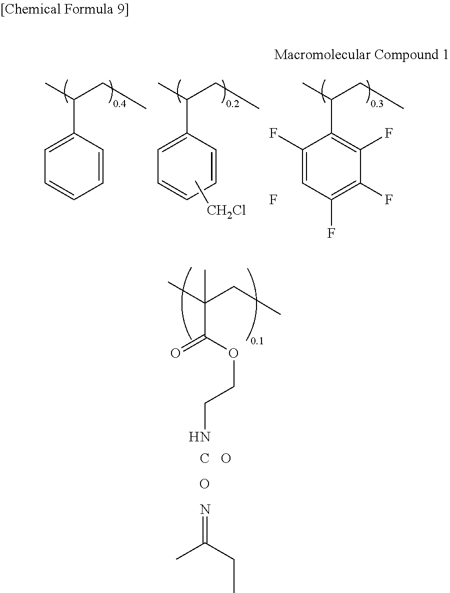

Weight average molecular weight of the resulting macromolecular compound 1 calculated from reference polystyrene was 18100 (GPC manufactured by SHIMADZU CORPORATION, one Tskgel super HM-H column and one Tskgel super H2000 column, mobile phase=THF).

### Synthesis Example 2

In a 50 ml pressure-resistant container (produced by ACE), 11.32 g of 2,3,4,5,6-pentafluorostyrene (produced by Aldrich Chemical Company, Inc.), 2.54 g of vinylbenzyl chloride (produced by Aldrich Chemical Company, Inc.), 2.00 g of 2-[0-[1′-methylpropylideneamino]carboxyamino]ethyl-methacrylate (produced by Showa Denko K. K., trade name “Karenz MOI-BM”), 0.08 g of 2,2′-azobis (2-methylpropionitrile) and 10.63 g of 2-heptanone (produced by Wako Pure Chemical Industries, Ltd.) were put, the resulting mixture was bubbled with an argon gas, and then the container was stopped tightly. Polymerization was carried out in an oil bath of 60° C. for 20 hours. After the completion of polymerization, 13.29 g of 2-heptanone was added to obtain a viscous 2-heptanone solution containing a macromolecular compound 2 dissolved therein. The macromolecular compound 2 has the following repeating unit. A suffix to a parenthesis indicates mole fraction of a repeating unit.

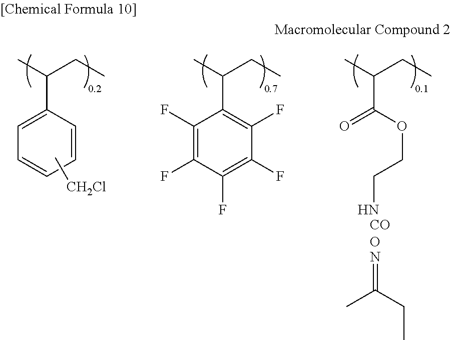

Weight average molecular weight of the resulting macromolecular compound 2 calculated from reference polystyrene was 160000 (GPC manufactured by SHIMADZU CORPORATION, one Tskgel super HM-H column and one Tskgel super H2000 column, mobile phase=THF).

### Synthesis Example 3

To 80 ml of toluene containing 6.40 g of 9,9-di-n-octylfluorene-2,7-di (ethylene boronate) and 4.00 g of 5,5′-dibromo-2,2′-bithiophene were added under nitrogen 0.18 g of tetrakis(triphenyl phosphine)palladium, 1.0 g of methyltrioctylammonium chloride (produced by Aldrich Chemical Company, Inc., trade name “Aliquat 336” (registered trademark)) and 24 mL of 2 M aqueous sodium carbonate solution. The resulting mixture was stirred vigorously and heated to reflux for 24 hours. A viscous reaction mixture was poured into 500 mL of acetone so that a fibrous yellow polymer was precipitated. This polymer was collected by filtration, washed with acetone, and dried at 60° C. in a vacuum oven overnight. The resulting polymer is called a macromolecular compound 3. The macromolecular compound 3 has the following repeating unit. n represents the number of the repeating units. Weight average molecular weight of the macromolecular compound 3 calculated from reference polystyrene was 61000 (GPC manufactured by SHIMADZU CORPORATION, one Tskgel super HM-H column and one Tskgel super H2000 column, mobile phase=THF).

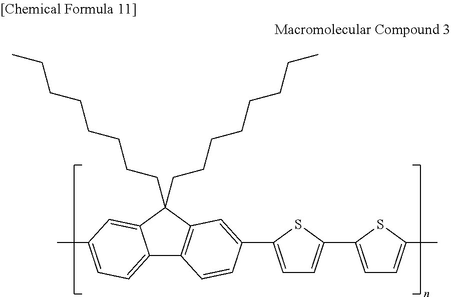

### Synthesis Example 4

In a 125 ml pressure-resistant container (produced by ACE). 7.14 g of styrene (produced by Wako Pure Chemical Industries, Ltd.), 10.00 g of 2,3,4,5,6-pentafluorostyrene (produced by Aldrich Chemical Company, Inc.), 5.98 g of vinylcinnamate (produced by Aldrich Chemical Company, Inc.), 4.12 g of 2-[0-[1′-methylpropylideneamino]carboxyamino]ethyl-methacrylate (produced by Showa Denko K.K., trade name “Karenz MOI-BM”), 0.10 g of 2,2′-azobis(2-methylpropionitrile) and 18.23 g of 2-heptanone (produced by Wako Pure Chemical Industries, Ltd.) were put, the resulting mixture was bubbled with an argon gas, and then the container was stopped tightly. Polymerization was carried out in an oil bath of 60° C. for 20 hours. After the completion of polymerization, 45.58 g of 2-heptanone was added to obtain a viscous 2-heptanone solution containing a macromolecular compound 4 dissolved therein. The macromolecular compound 4 has the following repeating unit. A suffix to a parenthesis indicates mole fraction of a repeating unit.

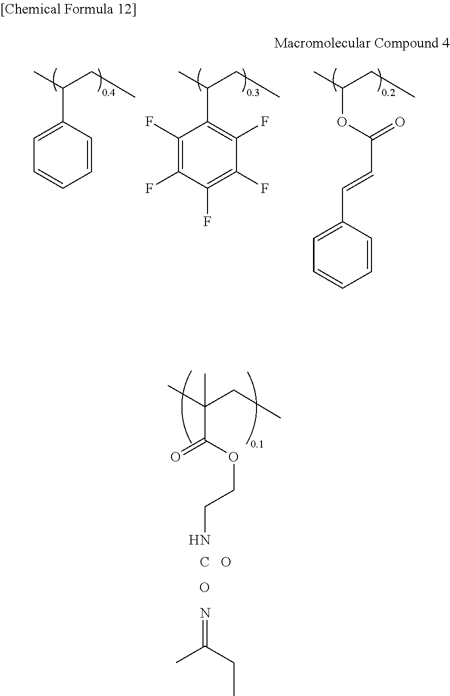

Weight average molecular weight of the resulting macromolecular compound 4 calculated from reference polystyrene was 241000 (GPC manufactured by SHIMADZU CORPORATION, one Tskgel super HM-H column and one Tskgel super H2000 column, mobile phase=THF).

### Synthesis Example 5

In a 125 ml pressure-resistant container (produced by ACE), 15.00 g of 2,3,4,5,6-pentafluorostyrene (produced by Aldrich Chemical Company, Inc.), 8.97 g of vinylcinnamate (produced by Aldrich Chemical Company, Inc.), 6.18 g of 2-[0-[1′-methylpropylideneamino]carboxyamino]ethyl-methacrylate (produced by Showa Denko K.K., trade name “Karenz MOI-BM”), 0.15 g of 2,2′-azobis(2-methylpropionitrile) and 20.21 g of 2-heptanone (produced by Wako Pure Chemical Industries, Ltd.) were put, the resulting mixture was bubbled with an argon gas, and then the container was stopped tightly. Polymerization was carried out in an oil bath of 60° C. for 20 hours. After the completion of polymerization, 50.51 g of 2-heptanone was added to obtain a viscous 2-heptanone solution containing a macromolecular compound 5 dissolved therein. The macromolecular compound 5 has the following repeating unit. A suffix to a parenthesis indicates mole fraction of a repeating unit.

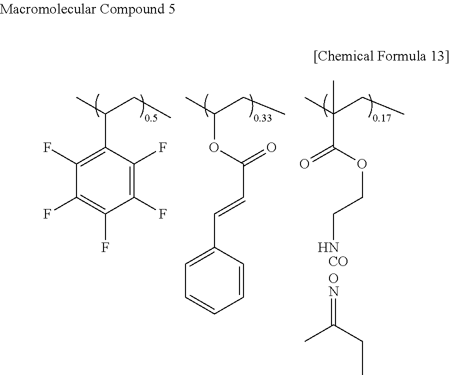

Weight average molecular weight of the resulting macromolecular compound 5 calculated from reference polystyrene was 463000 (GPC manufactured by SHIMADZU CORPORATION, one Tskgel super HM-H column and one Tskgel super H2000 column, mobile phase=THF).

### Synthesis Example 6

In a 125 ml pressure-resistant container (produced by ACE), 10.00 g of 2,3,4,5,6-pentafluorostyrene (produced by Aldrich Chemical Company, Inc.), 3.71 g of 4-hydroxybutyl acrylate (produced by KOHJIN Co., Ltd.), 1.50 g of vinylcinnamate (produced by Aldrich Chemical Company, Inc.), 0.08 g of 2,2′-azobis(2-methylpropionitrile) and 22.92 g of 2-heptanone (produced by Wako Pure Chemical Industries, Ltd.) were put, the resulting mixture was bubbled with an argon gas, and then the container was stopped tightly. Polymerization was carried out in an oil bath of 60° C. for 20 hours. After the completion of polymerization, 38.20 g of 2-heptanone was added to obtain a viscous 2-heptanone solution containing a macromolecular compound 6 dissolved therein. The macromolecular compound 6 has the following repeating unit. A suffix to a parenthesis indicates mole fraction of a repeating unit. The macromolecular compound 6 is a compound containing at least two active hydrogen atoms in its molecule.

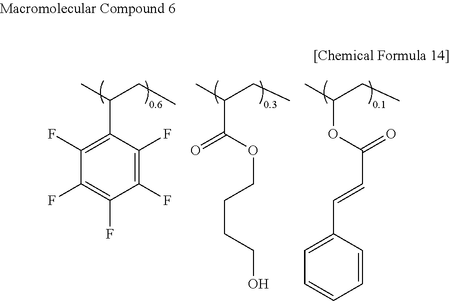

Weight average molecular weight of the resulting macromolecular compound 6 calculated from reference polystyrene was 176000 (GPC manufactured by SHIMADZU CORPORATION, one Tskgel super HM-H column and one Tskgel super H2000 column, mobile phase=THF).

### Synthesis Example 7

In a 125 ml pressure-resistant container (produced by ACE), 20.00 g of 2,3,4,5,6-pentafluorostyrene (produced by Aldrich Chemical Company, Inc.), 6.13 g of 4-aminostyrene (produced by Aldrich Chemical Company, Inc.), 2.99 g of vinylcinnamate (produced by Aldrich Chemical Company, Inc.), 0.15 g of 2,2′-azobis(2-methylpropionitrile) and 43.90 g of 2-heptanone (produced by Wako Pure Chemical Industries, Ltd.) were put, the resulting mixture was bubbled with an argon gas, and then the container was stopped tightly. Polymerization was carried out in an oil bath of 60° C. for 20 hours to obtain a viscous 2-heptanone solution containing a macromolecular compound 7 dissolved therein. The macromolecular compound 7 has the following repeating unit. A suffix to a parenthesis indicates mole fraction of a repeating unit. The macromolecular compound 7 is a compound containing at least two active hydrogen atoms in its molecule.

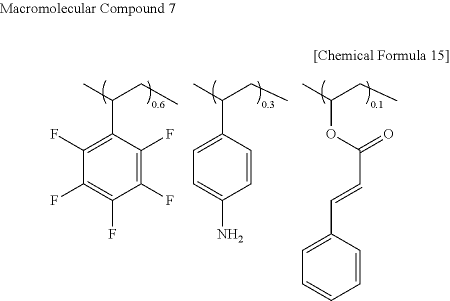

Weight average molecular weight of the resulting macromolecular compound 7 calculated from reference polystyrene was 199000 (GPC manufactured by SHIMADZU CORPORATION, one Tskgel super HM-H column and one Tskgel super H2000 column, mobile phase=THF).

### Synthesis Example 8

In a 100 ml three-necked flask equipped with a three-way cock, 20.07 g of 3-vinylbenzaldehyde (produced by Aldrich Chemical Company, Inc.), 23.00 g of acetophenone (produced by Aldrich Chemical Company, Inc.) and a stirring bar were put, and the resulting mixture was stirred with a magnetic stirrer to prepare a uniform reaction mixture solution. The flask was immersed in an ice bath and a catalytic amount of concentrated sulfuric acid was added to the reaction mixture solution with stirring to react the mixture for 1 hour under storage in ice. The ice bath was removed, and stirring of the reaction mixture solution was continued at room temperature to react the solution until the dissipation of a peak of vinylbenzaldehyde of a raw material was recognized by NMR analysis. After the completion of the reaction, the reaction mixture was placed in a separating funnel, and to this, 100 ml of diethyl ether was added and the resulting mixture was washed with water repeatedly until a water layer became neutral. After the completion of water wash, an organic layer was separated from the mixture and dried over magnesium sulfate, and a filtrate liquid was concentrated by a rotary evaporator to obtain a crude product of 3-vinylstrylphenyl ketone. 3-vinylstrylphenyl ketone contained in the crude product was a mixture of a cis-form and a trans-form. Purity of 3-vinylstrylphenyl ketone determined by NMR was 74%.

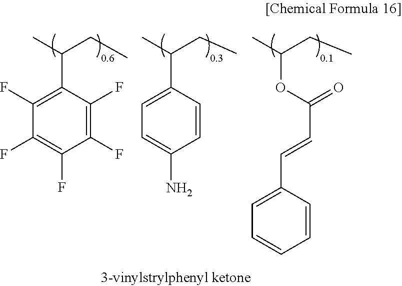

In a 50 ml pressure-resistant container (produced by ACE), 2.00 g of 2,3,4,5,6-pentafluorostyrene (produced by Aldrich Chemical Company, Inc.), 2.50 g of styrene (produced by Aldrich Chemical Company, Inc.), 6.55 g of a crude product of 3-vinylstrylphenyl ketone, 3.30 g of 2-[0-[1′-methylpropylideneamino]carboxyamino]ethyl-methacrylate (produced by Showa Denko K.K., trade name “Karenz MOI-BM”), 0.07 g of 2,2′-azobis(2-methylpropionitrile) and 21.63 g of 2-heptanone (produced by Wako Pure Chemical Industries, Ltd.) were put, the resulting mixture was bubbled with an argon gas, and then the container was stopped tightly. Polymerization was carried out in an oil bath of 60° C. for 20 hours. After the completion of the reaction, the reactant was reprecipitated with methanol to obtain a macromolecular compound 8. The macromolecular compound 8 has the following repeating unit. A suffix to a parenthesis indicates mole fraction of a repeating unit.

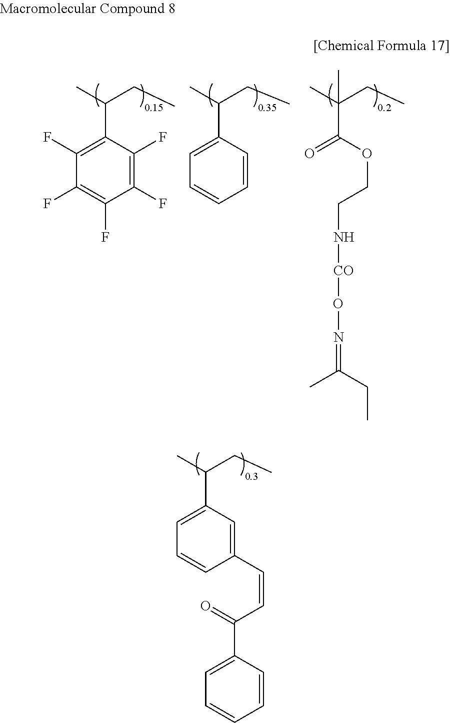

Weight average molecular weight of the resulting macromolecular compound 8 calculated from reference polystyrene was 98000 (GPC manufactured by SHIMADZU CORPORATION, one Tskgel super HM-H column and one Tskgel super H2000 column, mobile phase=THF).

### Synthesis Example 9

In a 500 ml three-necked flask equipped with a three-way cock, 25.00 g of cyano acetate (produced by Wako Pure Chemical Industries, Ltd.), 12.34 g of sodium hydroxide (produced by Wako Pure Chemical Industries, Ltd.), 250 ml of ion-exchange water and a stirring bar were put, and the resulting mixture was stirred with a magnetic stirrer to prepare a uniform reaction mixture solution. The flask was immersed in an ice bath and 38.84 g of cinnamic aldehyde was added dropwise to the reaction mixture solution while stirring it. The mixture was reacted for 1 hour under storage in ice, the ice bath was removed, and then was further reacted at room temperature for 4 hours. After the completion of the reaction, concentrated hydrochloric acid was added dropwise to the reaction mixture until a liquid component in the reaction mixture became acidic. A precipitated solid was separated by filtration through a glass filter, washed with ion-exchange water until the filtrate liquid became neutral, and dried in a vacuum oven to obtain cyanocinnamylidene acetic acid. Yield thereof was 39.68 g.

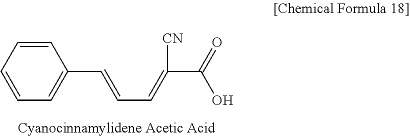

In a 50 ml pressure-resistant container (produced by ACE), 2.00 g of 2,3,4,5,6-pentafluorostyrene (produced by Aldrich Chemical Company, Inc.), 2.50 g of styrene (produced by Aldrich Chemical Company, Inc.), 2.68 g of 2-hydroxyethyl methacrylate, 3.30 g of 2-[0-[1′-methylpropylideneamino]carboxyamino]ethyl-methacrylate (produced by Showa Denko K.K., trade name “Karenz MOI-BM”), 0.05 g of 2,2′-azobis(2-methylpropionitrile) and 15.80 g of propylene glycol monomethyl ether acetate (produced by Wako Pure Chemical Industries, Ltd.) were put, the resulting mixture was bubbled with an argon gas, and then the container was stopped tightly. Polymerization was carried out in an oil bath of 60° C. for 20 hours to prepare a resin solution.

In a 300 ml three-necked flask equipped with a three-way cock, the obtained resin solution, 4.31 g of the cyanocinnamylidene acetic acid, a catalytic amount of N,N-dimethylaminopyridine and 100 ml of dehydrated were put, and the resulting mixture was stirred with a magnetic stirrer to prepare a uniform reaction mixture solution. To the obtained reaction mixture solution, a dioxane solution of dicyclohexylcarbodiimide prepared by dissolving 4.46 g of N,N′-dicyclohexylcarbodiimide in 50 ml of dehydrated dioxane was added dropwise was added dropwise at roomtemperature. After completion of the addition, the resulting mixture was stirred at room temperature overnight to be reacted. After the completion of the reaction, a precipitated substance was filtered and a filtrate solution was reprecipitated with 2-propanol to obtain a macromolecular compound 9. The macromolecular compound 9 has the following repeating unit. A suffix to a parenthesis indicates mole fraction of a repeating unit.

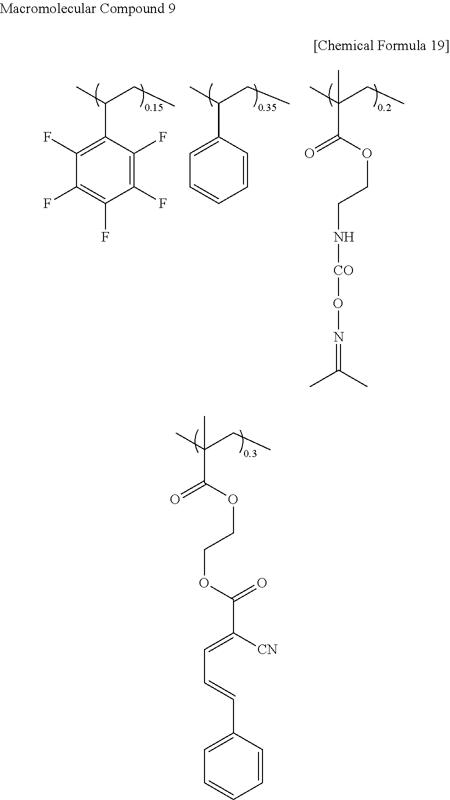

Weight average molecular weight of the resulting macromolecular compound 9 calculated from reference polystyrene was 167000 (GPC manufactured by SHIMADZU CORPORATION, one Tskgel super HM-H column and one Tskgel super H2000 column, mobile phase=THF).

### Example 1

### Production of Insulating Layer Material for Organic Thin Film Transistor and Electric Field Effect Type Organic Thin Film Transistor

Into a 10 ml sample bottle were charged 2.00 g of a 2-heptanone solution of the macromolecular compound 1 obtained in Synthesis Example 1, 0.029 g of hydroquinone, which is a compound containing at least two active hydrogen atoms in its molecule and 4.00 g of 2-heptanone, and the resulting mixture was dissolved while being stirred to prepare a uniform coating solution containing an organic thin film transistor insulating layer material.

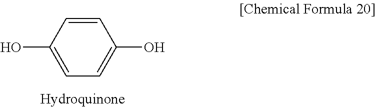

The resulting coating solution was filtered through a membrane filter having a pore diameter of 0.2 μm, applied onto a glass substrate with a chromium electrode by spin coating, and then baked on a hot plate at 220° C. for 30 minutes. Thereafter, a baked coat on the substrate was irradiated with UV light at room temperature for 2 minutes by the use of a UV-Ozone stripper (UV-1 manufactured by SAMCO Inc.) in a nitrogen atmosphere to obtain a gate insulating layer.

Then, the macromolecular compound 3 was dissolved in chloroform as a solvent to prepare a solution (organic semiconductor composition) having a concentration of 0.5% by weight, and this was filtered through a membrane filter to prepare a coating solution.

The resulting coating solution was applied onto the gate insulating layer by a spin coating method to form an active layer having a thickness of about 60 nm, and subsequently a source electrode and a drain electrode (each of the electrodes having a laminated structure in the order of molybdenum oxide and gold from the active layer side) each having a channel length of 20 μm and a channel width of 2 mm were formed on the active layer by a vacuum deposition method using a metal mask, and thereby an electric field effect type organic thin film transistor was produced.

### Example 2

### Production of Insulating Layer Material for Organic Thin Film Transistor and Electric Field Effect Type Organic Thin Film Transistor

Into a 10 ml sample bottle were charged 2.00 g of a 2-heptanone solution of the macromolecular compound 2 obtained in Synthesis Example 2, 0.023 g of hydroquinone and 4.00 g of 2-heptanone, and the resulting mixture was stirred and dissolved to prepare a uniform coating solution containing an organic thin film transistor insulating layer material.

The resulting coating solution was filtered through a membrane filter having a pore diameter of 0.2 μm, applied onto a glass substrate with a chromium electrode by spin coating, and then baked on a hot plate at 220° C. for 30 minutes. Thereafter, a baked coat on the substrate was irradiated with UV light at room temperature for 2 minutes by the use of a UV-Ozone stripper (UV-1 manufactured by SAMCO Inc.) in a nitrogen atmosphere to obtain a gate insulating layer.

Next, as with Example 1, an active layer, a source electrode and a drain electrode were formed to prepare an electric field effect type organic thin film transistor.

### Example 3

### Production of Insulating Layer Material for Organic Thin Film Transistor and Electric Field Effect Type Organic Thin Film Transistor

Into a 150 ml sample bottle were charged 45.00 g of a 2-heptanone solution of the macromolecular compound 4 obtained in Synthesis Example 4, 25.11 g of a 2-heptanone solution of the macromolecular compound 6 obtained in Synthesis Example 6 and 35.10 g of 2-heptanone, and the resulting mixture was stirred and dissolved to prepare a uniform coating solution containing an organic thin film transistor insulating layer material.

The resulting coating solution was filtered through a membrane filter having a pore diameter of 0.2 μm, applied onto a glass substrate with a chromium electrode by spin coating, and then baked on a hot plate at 100° C. for 10 minutes. Thereafter, a baked coat on the substrate was irradiated with UV light (wavelength 365 nm) of 3000 mJ/cm² by the use of an aligner (PLA-521 manufactured by Canon Inc.) and then baked at 200° C. for 30 minutes on a hot plate in a nitrogen atmosphere to obtain a gate insulating layer.

Next, as with Example 1, an active layer, a source electrode and a drain electrode were formed to prepare an electric field effect type organic thin film transistor.

### Example 4

### Production of Insulating Layer Material for Organic Thin Film Transistor and Electric Field Effect Type Organic Thin Film Transistor

Into a 150 ml sample bottle were charged 41.21 g of a 2-heptanone solution of the macromolecular compound 4 obtained in Synthesis Example 4, 11.01 g of a 2-heptanone solution of the macromolecular compound 7 obtained in Synthesis Example 7 and 50.00 g of 2-heptanone, and the resulting mixture was stirred and dissolved to prepare a uniform coating solution containing an organic thin film transistor insulating layer material.

The resulting coating solution was filtered through a membrane filter having a pore diameter of 0.2 μm, applied onto a glass substrate with a chromium electrode by spin coating, and then baked on a hot plate at 100° C. for 10 minutes. Thereafter, a baked coat on the substrate was irradiated with UV light (wavelength 365 nm) of 3000 mJ/cm² by the use of an aligner (PLA-521 manufactured by Canon Inc.) and then baked at 200° C. for 30 minutes on a hot plate in a nitrogen atmosphere to obtain a gate insulating layer.

Next, as with Example 1, an active layer, a source electrode and a drain electrode were formed to prepare an electric field effect type organic thin film transistor.

### Example 5

### Production of Insulating Layer Material for Organic Thin Film Transistor and Electric Field Effect Type Organic Thin Film Transistor

Into a 150 ml sample bottle were charged 45.00 g of a 2-heptanone solution of the macromolecular compound 5 obtained in Synthesis Example 5, 16.62 g of a 2-heptanone solution of the macromolecular compound 7 obtained in Synthesis Example 7 and 57.00 g of 2-heptanone, and the resulting mixture was stirred and dissolved to prepare a uniform coating solution containing an organic thin film transistor insulating layer material.

The resulting coating solution was filtered through a membrane filter having a pore diameter of 3 μm, applied onto a glass substrate with a chromium electrode by spin coating, and then baked on a hot plate at 100° C. for 10 minutes. Thereafter, a baked coat on the substrate was irradiated with UV light (wavelength 365 nm) of 3000 mJ/cm² by the use of an aligner (PLA-521 manufactured by Canon Inc.) and then baked at 200° C. for 30 minutes on a hot plate in a nitrogen atmosphere to obtain a gate insulating layer.

Next, as with Example 1, an active layer, a source electrode and a drain electrode were formed to prepare an electric field effect type organic thin film transistor.

### Example 6

### Production of Insulating Layer Material for Organic Thin Film Transistor and Electric Field Effect Type Organic Thin Film Transistor

Into a 30 ml sample bottle were charged 0.5 g of the macromolecular compound 8 obtained in Synthesis Example 8, 0.068 g of 1,3-bis(3′-aminophenoxy)benzene and 2.5 g of 2-heptanone, and the resulting mixture was stirred and dissolved to prepare a uniform coating solution containing an organic thin film transistor insulating layer material.

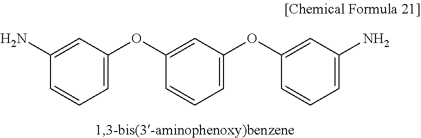

The resulting coating solution was filtered through a membrane filter having a pore diameter of 0.5 μm, applied onto a glass substrate with a chromium electrode by spin coating, and then baked on a hot plate at 100° C. for 10 minutes. Thereafter, a baked coat on the substrate was irradiated with UV light (wavelength 365 nm) of 1600 mJ/cm² by the use of an aligner (PLA-521 manufactured by Canon Inc.) and then baked at 220° C. for 30 minutes on a hot plate in the air to obtain a gate insulating layer.

Next, as with Example 1, an active layer, a source electrode and a drain electrode were formed to prepare an electric field effect type organic thin film transistor.

### Example 7

### Production of Insulating Layer Material for Organic Thin Film Transistor and Electric Field Effect Type Organic Thin Film Transistor

Into a 30 ml sample bottle were charged 0.63 g of the macromolecular compound 9 obtained in Synthesis Example 9, 0.079 g of 1,3-bis(3′-aminophenoxy)benzene and 5.38 g of cyclopentanone, and the resulting mixture was stirred and dissolved to prepare a uniform coating solution containing an organic thin film transistor insulating layer material.

The resulting coating solution was filtered through a membrane filter having a pore diameter of 0.5 μm, applied onto a glass substrate with a chromium electrode by spin coating, and then baked on a hot plate at 100° C. for 10 minutes. Thereafter, a baked coat on the substrate was irradiated with UV light (wavelength 365 nm) of 1600 mJ/cm² by the use of an aligner (PLA-521 manufactured by Canon Inc.) and then baked at 220° C. for 30 minutes on a hot plate in the air to obtain a gate insulating layer.

Next, as with Example 1, an active layer, a source electrode and a drain electrode were formed to prepare an electric field effect type organic thin film transistor.

### <Evaluation of Transistor Characteristics>

With respect to the thus-produced electric field effect type organic thin film transistors, the transistor characteristics thereof were measured by using a vacuum prober (BCT22MDC-5-HT-SCU; manufactured by Nagase Electronic Equipment Service Co., Ltd.) under such conditions that a gate voltage Vg was varied from 0 to −40 V and a source-drain voltage Vsd was varied from 0 to −40 V, and the results are given in Table 1.

With respect to a comparative example, the transistor characteristics thereof were measured under such conditions that a gate voltage Vg was varied from 0 to −60 V and a source-drain voltage Vsd was varied from 0 to −40 V.

The hysteresis of an electric field effect type organic thin film transistor was expressed by a voltage difference between a threshold voltage Vth1 measured when the gate voltage Vg was varied from 0 V to −40 V at a source-drain voltage Vsd of −40 V and a threshold voltage Vth2 measured when the gate voltage Vg was varied from −40 V to 0 V.

### Comparative Example 1

### Production of Electric Field Effect Type Organic Thin Film Transistor

An electric field effect type organic thin film transistor was produced and the transistor characteristics thereof were measured and evaluated in the same manner as in Example 1 except that polyvinylphenol (produced by Aldrich Chemical Company, Inc., Mn=8000) was used in place of the macromolecular compound 1 and UV irradiation was not performed at the time of the formation of a gate insulating layer.

TABLE 1

| | Hysteresis | Vth1 |
|---|---|---|
| Example 1 | 0.4 V | −2.7 V |
| Example 2 | 0.2 V | 0.5 V |
| Example 3 | 0.1 V | −0.4 V |
| Example 4 | 0.6 V | −4.2 V |
| Example 5 | 0.0 V | −1.3 V |
| Example 6 | 0.5 V | −11.1 V |
| Example 7 | 0.0 V | −5.0 V |
| Comparative | 3.5 V | −50.0 V |
| Example 1 | | |

### DESCRIPTION OF THE REFERENCE NUMERALS

1 Substrate
2 gate electrode
3 gate insulating layer
4 organic semiconductor layer
5 source electrode
6 drain electrode
7 overcoat

1. An organic thin film transistor insulating layer material comprising:
a macromolecular compound (A) which contains repeating units represented by the formula: 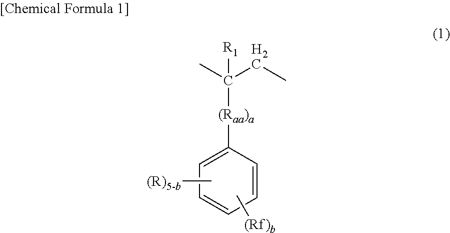
wherein R₁ represents a hydrogen atom or a methyl group; R represents a hydrogen atom or a monovalent organic group having 1 to 20 carbon atoms; Rf represents a fluorine atom or a monovalent organic group having a fluorine atom and having 1 to 20 carbon atoms; R₁ represents a linking moiety that links a main chain with a side chain; a hydrogen atom in the linking moiety may have been substituted with a fluorine atom; a represents an integer of 0 or 1 and b represents an integer of 1 to 5; when there are two or more R's, they may be the same or different; and when there are two or more Rf's, they may be the same or different; and repeating units each containing a functional group which absorbs optical energy or electron beam energy to cause a dimerization reaction, and contains two or more first functional groups in its molecule, wherein the first functional groups are each a functional group that generates, by the action of electromagnetic waves or heat, a second functional group which reacts with active hydrogen, and
at least one active hydrogen compound (B) selected from the group consisting of low-molecular compounds containing two or more active hydrogen atoms in each molecule and macromolecular compounds containing two or more active hydrogen atoms in each molecule.

2. The organic thin film transistor insulating layer material according to claim 1, wherein the repeating units each containing a functional group which absorbs optical energy or electron beam energy to cause a dimerization reaction are repeating units represented by the formula: 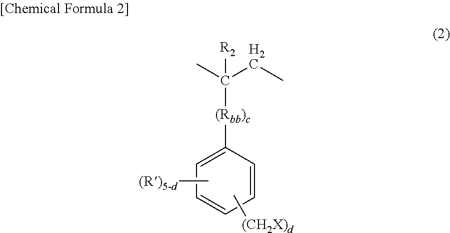
wherein R₂ represents a hydrogen atom or a methyl group; R′ represents a hydrogen atom or a monovalent organic group having 1 to 20 carbon atoms; R_{bb} represents a linking moiety that links a main chain with a side chain; a hydrogen atom in the linking moiety may have been substituted with a fluorine atom; c represents an integer of 0 or 1 and d represents an integer of 1 to 5; when there are two or more R's, they may be the same or different; and X represents a chlorine atom, a bromine atom or an iodine atom.

3. The organic thin film transistor insulating layer material according to claim 1, wherein the repeating units each containing a functional group which absorbs optical energy or electron beam energy to cause a dimerization reaction are repeating units represented by the formula: 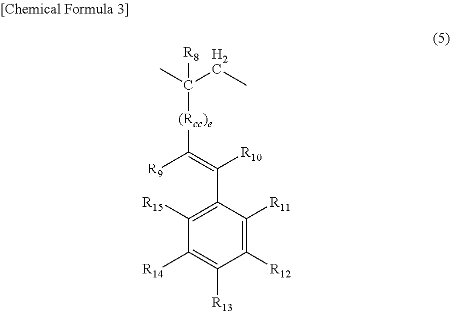
wherein R₈ represents a hydrogen atom or a methyl group; R₉ to R₁₅ are the same or different and represent a hydrogen atom or a monovalent organic group having 1 to 20 carbon atoms; R_{cc} represents a linking moiety that links a main chain with a side chain; a hydrogen atom in the linking moiety may have been substituted with a fluorine atom; and e represents an integer of 0 or 1.

4. The organic thin film transistor insulating layer material according to claim 1, wherein the repeating units each containing a functional group which absorbs optical energy or electron beam energy to cause a dimerization reaction are repeating units represented by the formula: 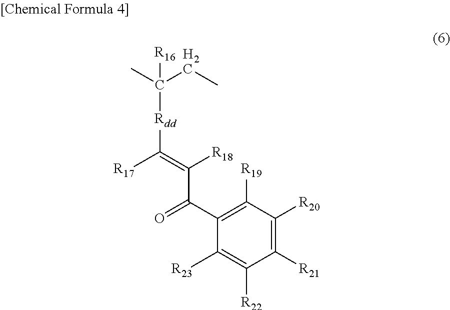
wherein R₁₆ represents a hydrogen atom or a methyl group; R₁₇ to R₂₃ are the same or different and represent a hydrogen atom or a monovalent organic group having 1 to 20 carbon atoms; R_{dd} represents a linking moiety that links a main chain with a side chain; and a hydrogen atom in the linking moiety may have been substituted with a fluorine atom.

5. The organic thin film transistor insulating layer material according to claim 1, wherein the first functional groups are groups of at least one member selected from the group consisting of an isocyanato group blocked with a blocking agent and an isothiocyanato group blocked with a blocking agent.

6. The organic thin film transistor insulating layer material according to claim 5, wherein the isocyanato group blocked with a blocking agent and the isothiocyanato group blocked with a blocking agent are groups represented by the formula: 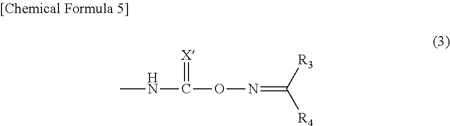
wherein X′ represents an oxygen atom or a sulfur atom, and R₃ and R₄ are the same or different and represent a hydrogen atom or a monovalent organic group having 1 to 20 carbon atoms.

7. The organic thin film transistor insulating layer material according to claim 5, wherein the isocyanato group blocked with a blocking agent and the isothiocyanato group blocked with a blocking agent are groups represented by the formula: 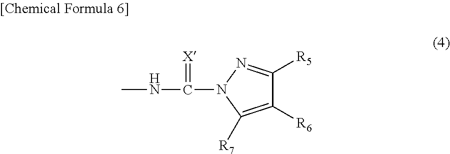
wherein X′ represents an oxygen atom or a sulfur atom, and R₅ to R₇ are the same or different and represent a hydrogen atom or a monovalent organic group having 1 to 20 carbon atoms.

8. A method for forming an insulating layer of an organic thin film transistor comprising the steps of:
applying a liquid containing the organic thin film transistor insulating layer material according to claim 1 onto a substrate to form an applied layer on the substrate;
irradiating the applied layer with light or electron beams to dimerize a functional group which absorbs optical energy or electron beam energy to cause a dimerization reaction in a macromolecular compound (A); and
applying electromagnetic waves or heat to the applied layer to generate a second functional group from a first functional group of the macromolecular compound (A) and reacting the second functional group with an active hydrogen-containing group of an active hydrogen compound (B).

9. The method for forming an insulating layer of an organic thin film transistor according to claim 8, wherein the light is ultraviolet light.

10. An organic thin film transistor having an insulating layer of an organic thin film transistor formed by using the organic thin film transistor insulating layer material according to claim 1.

11. The organic thin film transistor according to claim 10, wherein the insulating layer of an organic thin film transistor is a gate insulating layer.

12. A member for a display including the organic thin film transistor according to claim 10.

13. A display including the member for a display according to claim 12.

14. A macromolecular compound containing:
repeating units represented by the formula: 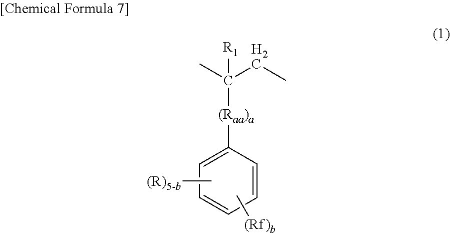
wherein R₁ represents a hydrogen atom or a methyl group; R represents a hydrogen atom or a monovalent organic group having 1 to 20 carbon atoms; Rf represents a fluorine atom or a monovalent organic group having a fluorine atom and having 1 to 20 carbon atoms; R₁ represents a linking moiety that links a main chain with a side chain; a hydrogen atom in the linking moiety may have been substituted with a fluorine atom; a represents an integer of 0 or 1 and b represents an integer of 1 to 5; when there are two or more R's, they may be the same or different; and when there are two or more Rf's, they may be the same or different,
repeating units represented by the formula: 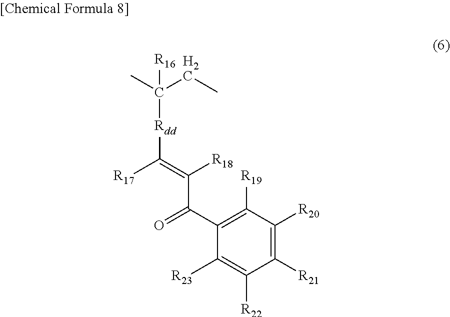
wherein R₁₆ represents a hydrogen atom or a methyl group; R₁₇ to R₂₃ are the same or different and represent a hydrogen atom or a monovalent organic group having 1 to 20 carbon atoms; R_{dd} represents a linking moiety that links a main chain with a side chain; and a hydrogen atom in the linking moiety may have been substituted with a fluorine atom, and
two or more first functional groups in its molecule, wherein the first functional groups are each a functional group that generates, by the action of electromagnetic waves or heat, a second functional group which reacts with active hydrogen.
